(19) United States
(12) Patent Application Publication
(10) Pub. No.: US 2026/0271679 A1
(43) Pub. Date: Sep. 10, 2026

(54) METHOD FOR MANUFACTURING SEMICONDUCTOR STRUCTURE USING MULTI-LAYERED HARD MASK

(71) Applicant: TAIWAN SEMICONDUCTOR MANUFACTURING COMPANY, LTD., Hsinchu (TW)

(72) Inventors: Shen-Yang Lee, Hsinchu (TW); Hsiang-Pi CHANG, Hsinchu (TW); Hsu-Kai CHANG, Hsinchu (TW); Chun-Fu LU, Hsinchu (TW); Huang-Lin CHAO, Hsinchu (TW); Pinyen LIN, Hsinchu (TW)

(73) Assignee: TAIWAN SEMICONDUCTOR MANUFACTURING COMPANY, LTD., Hsinchu (TW)

(21) Appl. No.: 19/073,782

(22) Filed: Mar. 7, 2025

(51) Int. Cl. H01L 21/027; G03F 1/80; H01L 21/033; H10D 30/01; H10D 30/62; H10D 62/10; H10D 80/20

(52) U.S. Cl. CPC H10P 76/2041; G03F 1/80; H10D 30/024; H10D 30/62; H10D 62/121; H10D 80/251; H10P 76/202; H10P 76/403; H10P 76/4085

(57) ABSTRACT

A method for manufacturing a semiconductor structure includes: forming a base structure having a first region and a second region; forming a hard mask unit having a first portion and a second portion which are respectively formed on the first and second regions, each of the first and second portions of the hard mask unit including an inner layer and an outer layer that are sequentially formed on the base structure and that are made of different materials; forming a patterned polymeric mask over the second portion of the hard mask unit; removing the first portion of the hard mask unit; and removing the patterned polymeric mask.

### BACKGROUND

As technology nodes continue to advance, the number of transistors on a chip is rapidly increasing, and thus device scaling is a key factor for development in the future. Shrinkage in the critical dimension of devices causes significant challenge in the patterning process, for example, more advanced lithography techniques and materials are required due to the increased complexity in creating accurate, high-resolution patterns. Achieving precise patterning in devices with relatively small critical dimension is crucial for maintaining performance, reducing power consumption, and enhancing overall chip functionality. Innovations in mask technology, etching processes, and pattern transfer techniques will be essential to overcome the aforesaid challenges, and to ensure the continued scaling of semiconductor devices, so as to define the future of integrated circuit design and manufacturing of the same.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 44 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

Source/drain feature(s) may refer to a source or a drain, individually or collectively dependent upon the context.

The present disclosure is directed to a method for forming a semiconductor structure which includes devices formed on different regions. The devices are formed to have different electrical properties by varying materials of, e.g., work function metals, and/or dipole layers in the formation of gate structure of the devices. The method includes: forming a hard mask unit over a base structure, the hard mask unit having a first portion and a second portion formed over a first region and a second region of the base structure, respectively; forming a patterned polymeric mask over the second region; removing the first portion of the hard mask unit; and removing the patterned polymeric mask. The hard mask unit is formed with an appropriate thickness so as to provide sufficient protection to elements underneath during a patterning process for forming the patterned polymeric mask. In addition, the hard mask unit is formed with multiple layers that exhibit different etching rates (i.e., different selectivities) when subjected to a same etchant. In removal of the first portion of the hard mask unit, the multiple layers are removed in a layer-by-layer approach using different etchants, so as to effectively minimize damages to the second portion of the hard mask unit. As such, a distance between the first region and the second region can be reduced (i.e., a smaller OD-OD distance) without having to consider potential damages caused by the removal of the first portion of the hard mask unit, thereby facilitating reduction in critical dimensions of the devices. The method may further include forming an intermediate layer, either after removing the first portion of the hard mask unit and the patterned polymeric mask, or prior to forming the hard mask unit, so as to facilitate formation of different elements (work function metal(s), dipole layer(s), diffusion barrier layer(s), or other suitable materials) on the different regions, thereby varying electrical properties of the devices at the different regions.

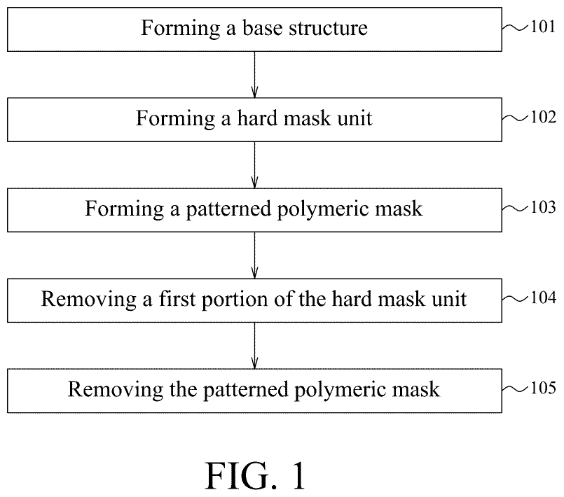

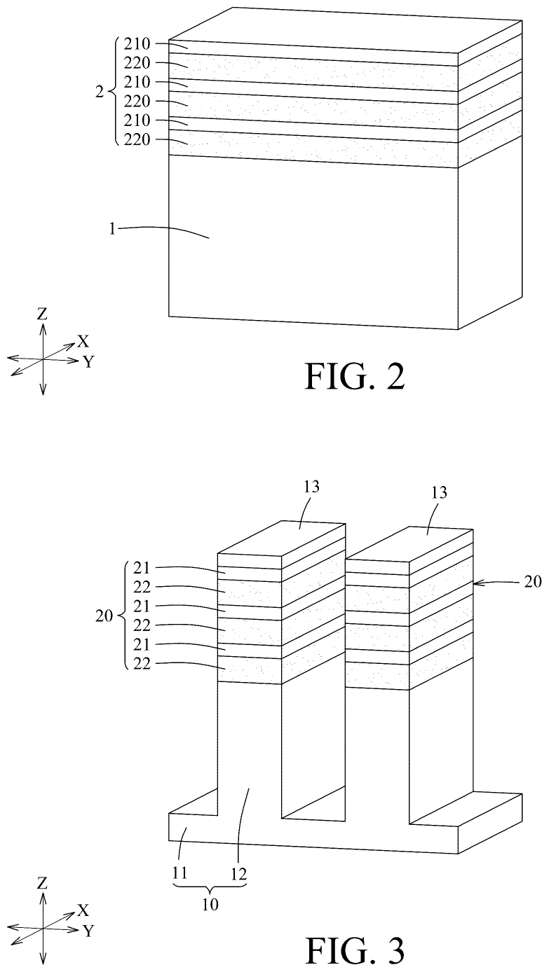

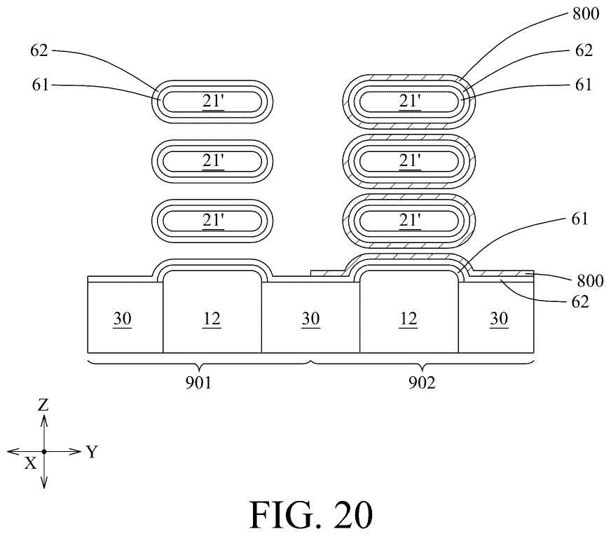

FIG. 1 is a flow diagram illustrating a method for manufacturing the semiconductor structure (for example, the semiconductor structure shown in FIGS. 20, 29, 32, 36, 44) in accordance with some embodiments. FIGS. 2 to 44 illustrate schematic views of intermediate stages of the method in accordance with some embodiments. Steps illustrated in FIGS. 2 to 44 are also illustrated schematically in the flow diagram shown in FIG. 1. Some repeating structures are omitted in FIGS. 2 to 44 for the sake of brevity. Additional steps can be provided before, after or during the method, and some of the steps described herein may be replaced by other steps or be eliminated.

Referring to FIG. 2, a material stack 2 is formed on a starting substrate 1.

The starting substrate 1 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The starting substrate 1 may be formed with an n-type well (not shown) having an n-type conductivity and/or a p-type well (not shown) having a p-type conductivity. Each of the n-type well and the p-type well may be formed by introducing an n-type impurity or a p-type impurity into the starting substrate 1 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some embodiments, the starting substrate 1 may be a bulk silicon substrate, a silicon-on-insulator (SOI) substrate, or a germanium-on-insulator (GOI) substrate. In some embodiments, the starting substrate 1 may be made of silicon. Other suitable materials for forming the starting substrate 1 are within the contemplated scope of the present disclosure.

The material stack 2 includes first material layers 210 and second material layers 220 that are alternatively stacked on each other over the starting substrate 1 and that may be formed using any suitable deposition processes, such as physical vapor deposition (PVD), chemical vapor deposition (CVD), atomic layer deposition (ALD), other suitable processes, or combinations thereof, but are not limited thereto. In the following description, a deposition process, unless otherwise stated or defined in this disclosure, may be performed in a way similar to the above-mentioned ones. In some embodiments, the first material layers 210 are made of a first semiconductor material, and the second material layers 220 are made of a second semiconductor material different from the first semiconductor material. Possible materials for the first and second semiconductor materials are similar to those for the starting substrate 1, and thus details thereof are omitted for the sake of brevity. In some embodiments, the material stack 2 includes three the first material layers 210, and three the second material layers 220. In some other embodiments, a number of the first material layers 210 or the second material layers 220 may be greater than three or smaller than three. In certain embodiments, the first material layers 210 include or are made of silicon, while the second nanosheet layers 220 include or are made of silicon germanium. In some embodiments, each of the first material layers 210 may have a thickness (measured in a Z direction) ranging from about 5 nm to about 8 nm, but are not limited thereto. In other embodiments, each of the second material layers 220 may have a thickness (measured in the Z direction) ranging from about 8 nm to about 12 nm, but are not limited thereto. Other suitable processes, materials, numbers and/or dimensions for each of the first and second material layers 210, 220 are within the contemplated scope of the present disclosure.

Referring to FIG. 3, a patterning process is performed to pattern the starting substrate 1 (see FIG. 2) into a patterned substrate 10 which includes a base 11 and fins 12 (which may referred to as protrusions on the base 11), and to pattern the material stack 2 (see FIG. 2) into fin stacks 20 which are respectively disposed on the fins 12.

The patterning process may include a photolithography process followed by an etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, unless otherwise stated or defined in this disclosure, may be performed in a way similar to the above-mentioned ones. In some embodiments, before the patterning process, a masking layer (not shown, may be made of silicon oxide, silicon nitride, other suitable materials, or combinations thereof) is formed on the material stack 2 using a suitable deposition process; and in the etching process, the masking layer is patterned by the patterned photoresist layer into masking regions 13, and then the starting substrate 1 and the material stack 2 are patterned using the masking regions 13 as an etching mask.

The fins 12 are disposed on the base 11, are each elongated in an X direction, and are spaced apart from each other in a Y direction transverse to (e.g., perpendicular to) the X direction. The fins 12 may be referred to as active regions. The fin stacks 20 are respectively disposed on the fins 12 opposite to the base 11 in the Z direction transverse to (e.g., perpendicular to) the X direction and the Y direction, and thus are spaced apart from each other in the Y direction. The first material layers 210 (see FIG. 2) are patterned to form channel layers 21 of the fin stacks 20; and the second material layers 220 (see FIG. 2) are patterned to form sacrificial layers 22 of the fin stacks 20. Each of the channel layers 21 may have a width (measured in the Y direction) ranging from about 15 nm to about 50 nm, but are not limited thereto. Other suitable processes and/or dimensions for the channel layers 21 and the sacrificial layers 22 are within the contemplated scope of the present disclosure.

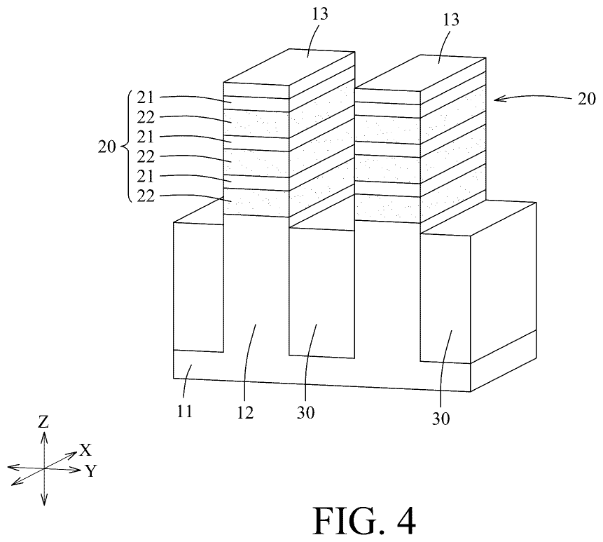

Referring to FIG. 4, isolation features 30 are formed. Each of the isolation features 30 is formed on the base 11 between two adjacent ones of the fins 12, and is elongated in the X direction. In some embodiments, the isolation features 30 are each a shallow isolation features (STI), a deep trench isolation (DTI), or other suitable structures. The isolation features 30 may be formed by: depositing an isolation material for forming the isolation features 30 using any suitable deposition processes over the structure shown in FIG. 3 such that the isolation material fills spaces among the fin stacks 20; performing a planarization process (e.g., chemical mechanical polishing (CMP)) to obtain a planarized surface, through which the masking regions 13 remaining respectively on the fin stacks 20 are exposed; and etching back the isolation material using any suitable etching processes, such as dry etching, wet etching, anisotropic etching, or combinations thereof. In the following description, an etching process, unless otherwise stated or defined in this disclosure, may be performed in a way similar to the above-mentioned ones. In some embodiments, after forming the isolation features 30, the masking regions 13 are removed. In some embodiments, upper surfaces of the isolation features 30 may be at a level lower than a level of upper surfaces of the fins 12. In some embodiments, the isolation features 30 include or are made of a dielectric material, such as an oxide-based material (e.g., silicon oxide, silicon oxynitride, silicon oxide formed from tetraethoxysilane (TEOS), or other suitable materials), silicon nitride, other low-k dielectric materials, or combinations thereof. Other suitable processes, materials and/or configurations of the isolation features 30 are within the contemplated scope of the present disclosure.

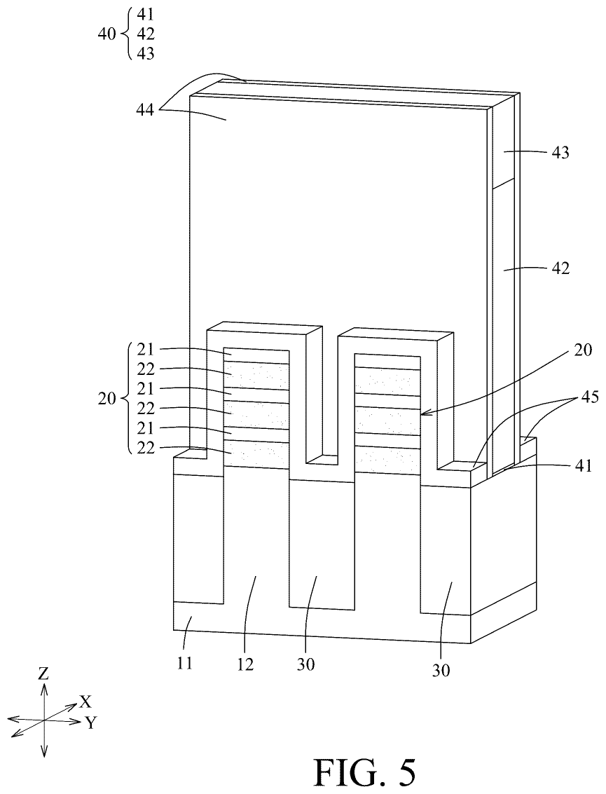

Referring to FIG. 5, a dummy structure 40 and a pair of gate spacers 44 are formed. In some embodiments, the dummy structure 40 is elongated in the Y direction and includes a dummy dielectric 41, a dummy gate 42, and a mask 43. The gate spacers 44 sandwich the dummy structure 40. Each of the fin stacks 20 has a first stack portion which is covered by the dummy structure 40 and the gate spacers 44, and second stack portions which are opposite to each other in the X direction to sandwich the first stack portion. In some embodiments, each of the second stack portions is covered by a corresponding one of fin sidewalls 45. The gate spacers 44 extend over the isolation features 30

In some embodiments, the dummy structure 40 is formed by: depositing first and second dummy layers (not shown) respectively for forming the dummy dielectric 41 and the dummy gate 42 using any suitable deposition processes; performing a planarization process (e.g., CMP) to obtain a planar upper surface of the second dummy layer (i.e., a planarized second dummy layer); forming a mask layer (not shown) for forming a mask 43 on the planarized second dummy layer using any suitable deposition processes; and patterning the first dummy layer, the planarized second dummy layer and the mask layer to partially expose the fin stacks 20 and the isolation features 30 using any suitable patterning processes and/or etching processes. Thereafter, a spacer material layer (not shown, for forming the gate spacers 44) is formed over the dummy structure 40, the fin stacks 20 and the isolation features 30 using any suitable deposition processes; and patterning the spacer material layer by any suitable patterning processes and/or etching processes, so as to obtain the gate spacers 44. In some embodiments, the fin sidewalls 45 are formed during forming the gate spacers 44. Other suitable processes for forming the dummy structure 40, the gate spacers 44 and the fin sidewalls 45 are within the contemplated scope of the present disclosure.

In some embodiments, the dummy dielectric 41 includes or is made of silicon oxide, silicon nitride, silicon oxynitride, high dielectric constant (k) materials, or combinations thereof. The dummy gate 42 includes or is made of polycrystalline silicon, single crystalline silicon, amorphous silicon, or combinations thereof. The mask 43 may be a single layer structure, or a multi-layered structure. The mask 43 includes or is made of a dielectric material, such as silicon nitride, silicon oxide, silicon oxynitride, or combinations thereof. The gate spacers 44 and the fin sidewall layers 45 may include or may be made of a same material or different materials. For instance, the gate spacers 44 and the fin sidewall layers 45 may include or may be made of a nitride-based material, such as silicon nitride, nitride-doped silicon oxide (which may be referred to as silicon oxynitride), silicon oxycarbon nitride, silicon carbon nitride, or combinations thereof. Other suitable materials for each of the dummy dielectric 41, the dummy gate 42, the mask 43, the gate spacers 44 and the fin sidewalls 45 are within the contemplated scope of the present disclosure.

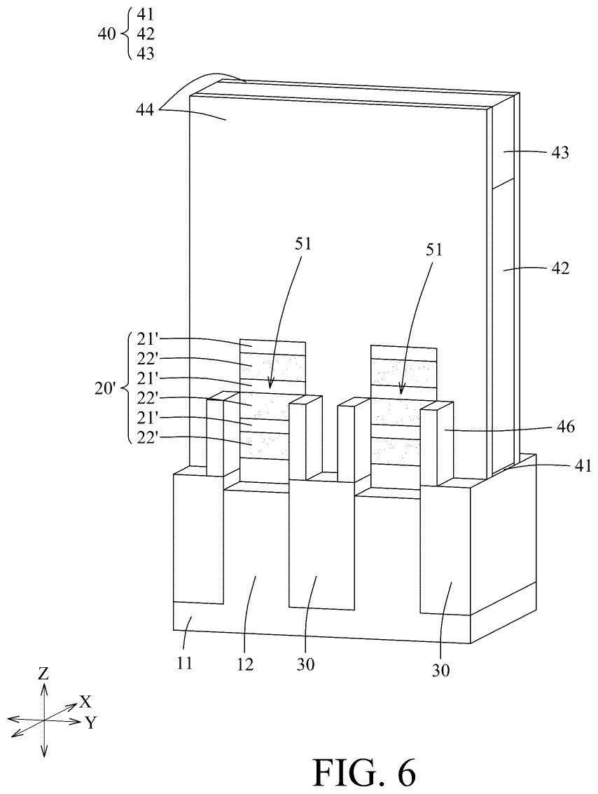

Referring to FIG. 6, the fin sidewalls 45 (see FIG. 5) are each patterned into fin sidewall portions 46, and the fin stacks 20 (see FIG. 5) are patterned into stack portions 20′ so as to form source/drain recesses 51.

After forming the fin sidewalls 46, in patterning the fin stacks 20, the second stack portions of the fin stacks 20 (see FIG. 5) are removed, and the first stack portions of the fin stacks 20 remain to serve as the stack portions 20′. The channel layers 21 (see FIG. 5) are formed into channel features 21′, and the sacrificial layers 22 are formed into sacrificial features 22′. In some embodiments, upper portions of the fins 12 are also patterned. Any suitable patterning processes and/or etching processes may be employed, while the mask 43 is provided to protect the dummy dielectric 41 and the dummy gate 42. Other suitable processes for forming the source/drain recesses 51 are within the contemplated scope of the present disclosure.

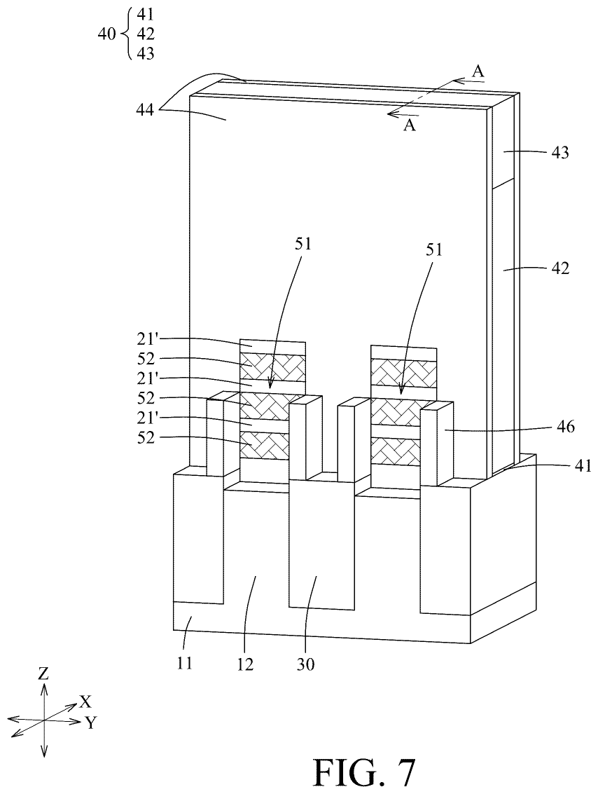

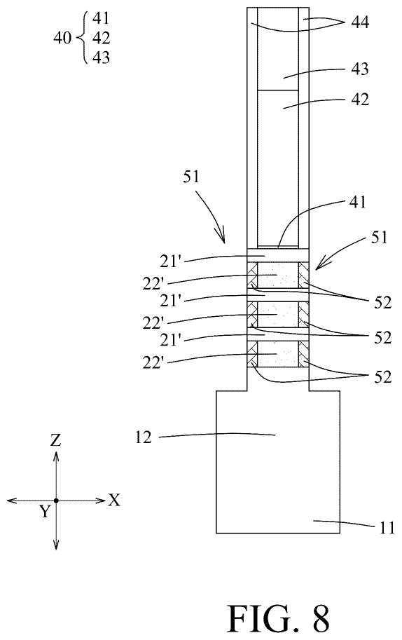

Referring to FIGS. 7 and 8, inner spacers 52 are formed. FIG. 8 is a cross-sectional view (x-cut) of the structure taken along the line A-A shown in FIG. 7.

In some embodiments, the inner spacers 52 are formed by: removing end regions of each of the sacrificial features 22′ (see FIG. 6) that are opposite to each other in the X direction using any suitable etching processes to form recesses (not shown); depositing an inner spacer material (not shown, for forming the inner spacers 52) to fill the recesses using any suitable deposition processes; and removing an excess amount of the inner spacer material using any suitable etching processes, thereby forming the inner spacer material into the inner spacers 52. In some embodiments, the inner spacers 52 (the inner spacer material) include or are made of silicon oxide, silicon oxycarbide, silicon nitride, silicon oxynitride, silicon carbide, silicon oxycarbonitride, air gap, other suitable low-k dielectric materials, or combinations thereof. Other suitable materials and/or processes for forming the inner spacers 52 are within the contemplated scope of the present disclosure.

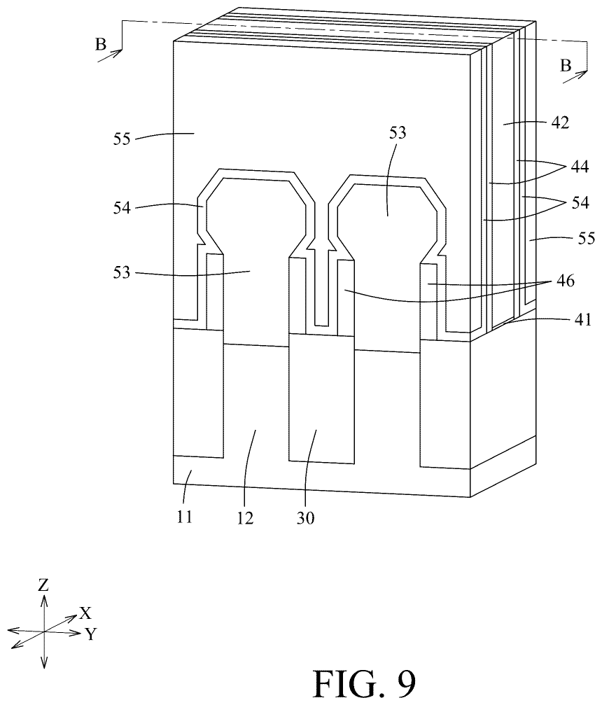

Referring to FIG. 9, source/drain features 53 (which may be referred to as epitaxial features), contact etch stop layers (CESLs) 54 and interlayer dielectrics (ILDs) 55 are formed.

In some embodiments, the source/drain features 53, the CESLs 54 and the ILDs 55 are formed by: forming the source/drain features 53 respectively in the source/drain recesses 51 (see FIGS. 7 and 8); sequentially depositing a first dielectric material (not shown, for forming the CESLs 54) and a second dielectric material (not shown, for forming the ILDs 55) over the source/drain features 53; and performing a planarization process (e.g., CMP, but is not limited thereto) to remove an excess amount of each of the first and second dielectric material, and to remove the mask 43 (see FIG. 7). Thereafter, the dummy gate 42 is exposed and each of the source/drain features 53 is formed beneath one of the CESLs 54 and a corresponding one of the ILDs 55. Although an interface between each of the isolation features 30 and a corresponding one of the CESLs 54 is a planar in FIG. 9, in some embodiments, the interface is non-planer. In addition, the CESLs 54 and the ILDs 55 are located above the isolation features 30. Since the upper portions of the fins 12 are also patterned and recessed during forming the source/drain recesses 51 (see FIG. 6), each of the source/drain features 53 is partially embedded in a corresponding one of fins 12. In some embodiments, each of the source/drain features 53 has a thickness in the Z direction and a width in the Y direction, the thickness of each of the source/drain features 53 is different from the width, and the width of each of the source/drain features 53 is different from the thickness. In some embodiments, a portion of each of the source/drain features 53 overhangs a corresponding one of the isolation features 30.

In some embodiments, the source/drain features 53 include or are made of single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain features 53 may each be doped with n-type dopant(s) or p-type dopant(s). Examples for the n-type dopants and the p-type dopants are respectively similar to the n-type impurities and p-type impurities described above, and thus details thereof are omitted for the sake of brevity. In some embodiments, an epitaxy growth process (such as molecular-beam epitaxy (MBE), selective area epitaxy (SAE), etc.) or other suitable deposition techniques may be adopted for forming the source/drain features 53. In some embodiments, the source/drain features 53 may include single epitaxial layer or multiple epitaxy layers having different materials and/or different dopant concentrations. In some embodiments, the source/drain features 53 includes at least two epitaxy layers containing same semiconductor materials with different dopant concentrations. In forming the CESLs 54 and the ILDs 55, any suitable deposition processes may be adopted. Each of the CESL 54 and the ILD 55 may include or be made of a dielectric material such as silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or combinations thereof. The CESL 54 and the ILD 55 are made of different dielectric materials. Other suitable materials and/or processes for forming the source/drain features 53, the CESLs 54 and/or the ILDs 55 are within the contemplated scope of the present disclosure.

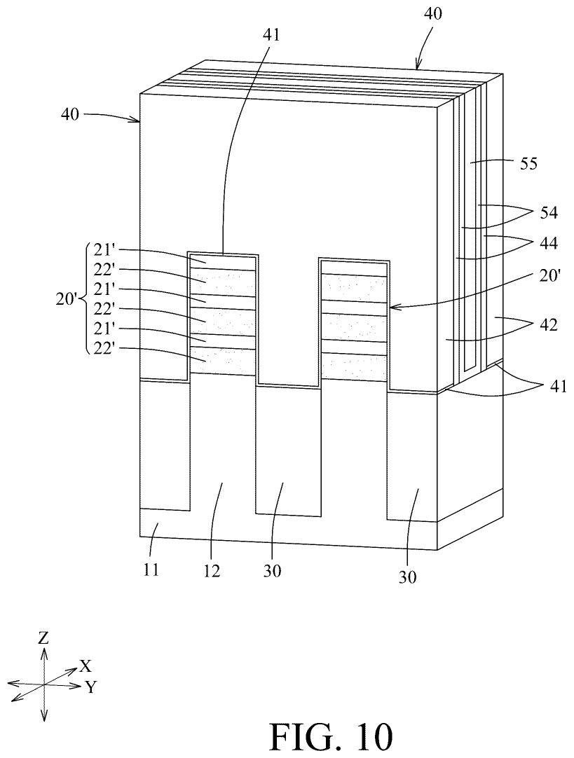

FIG. 10 is a cross-sectional view (y-cut) of the structure taken along the line B-B shown in FIG. 9. In FIG. 10, another repeating structure (including another remaining dummy structure 40) behind the CESL 54 and the ILD 55 is further shown. However, for sake of brevity, the remaining dummy structure 40 is still described in singular form.

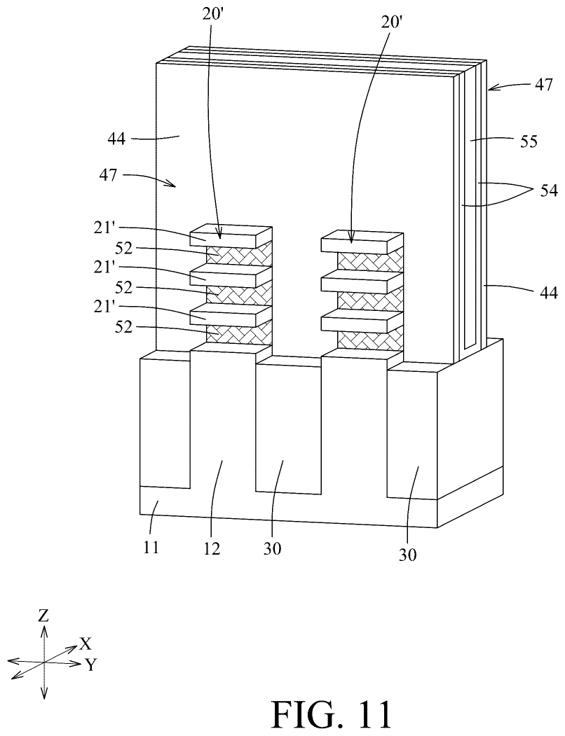

Referring to FIG. 11, the remaining dummy structure 40 (i.e., the dummy dielectric 41 and the dummy gate 42), and the remaining sacrificial features 22′ shown in FIG. 10 are removed to form a cavity 47.

The dummy dielectric 41, the dummy gate 42 and the remaining sacrificial features 22′ may be removed using any suitable etching processes. Other suitable processes for removing the dummy dielectric 41, the dummy gate 42 and the sacrificial features 22′ are within the contemplated scope of the present disclosure.

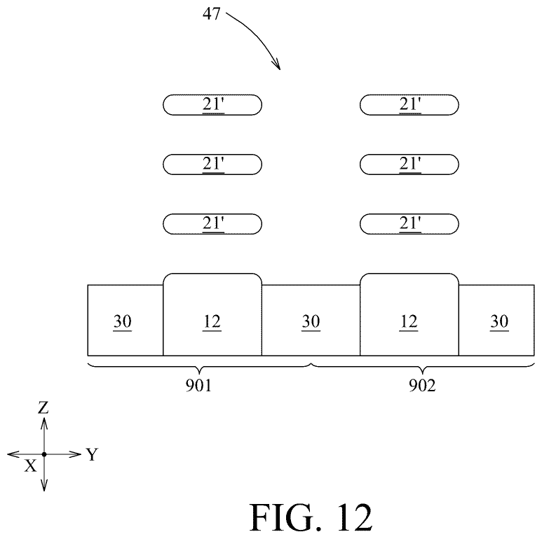

FIG. 12 is a schematic cross-sectional view (y-cut) illustrating some of the elements of the structure in the cavity 47 as shown in FIG. 11, while other elements (e.g., the inner spacers 52, the gate spacers 44, the source/drain features 53, the CESLs 54, and the ILDs 55) of the structure are not shown in FIG. 12. In some implementations, the channel features 21′ may each have a rectangular profile (see FIG. 11); however, in other implementations, the channel features 21′ may each have a rounded end profile (see FIG. 12). In the following drawings, the channel features 21′ are each represented with a rounded end profile.

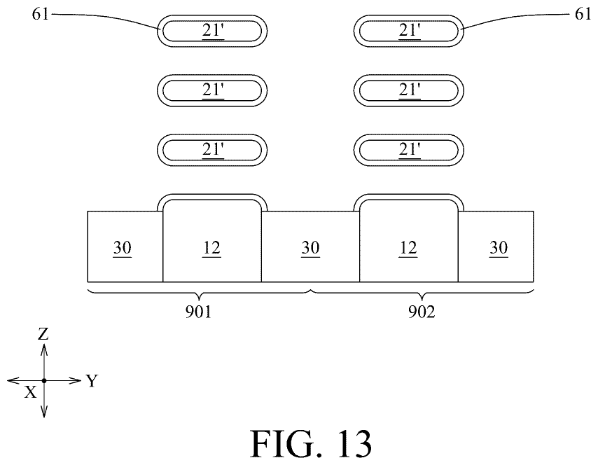

Referring to FIG. 13, interfacial layers (ILs) 61 are formed. The ILs 61 are respectively formed around the channel features 21′ and on the fins 12. In some embodiments, the ILs 61 include or are made of a dielectric material such as silicon oxide, silicon nitride, silicon oxynitride, or combinations thereof, but is not limited thereto. In some embodiments, the ILs 61 are formed using CVD, ALD (e.g., thermal ALD or plasma ALD), but are not limited thereto. Other suitable materials and/or processes for forming the ILs 61 are within the contemplated scope of the present disclosure.

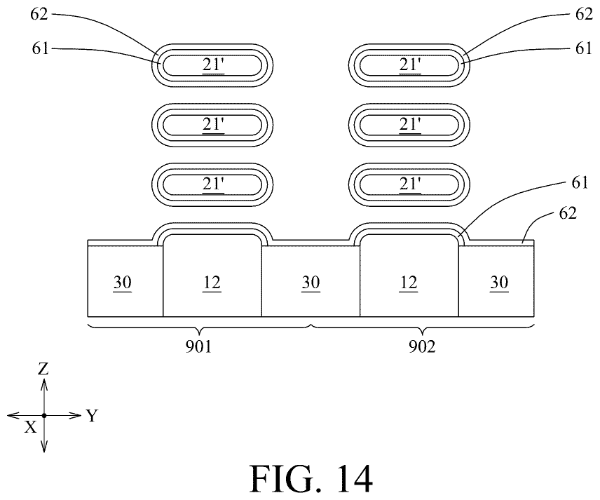

Referring to FIG. 14, a gate dielectric layer 62 is formed along the channel features 21′ and the isolation features 30. The gate dielectric layer 62 is formed over the structure shown in FIG. 13, and specifically, on the ILs 61 opposite to the channel features 21′ and the fins 12; on the isolation features 30; and on the gate spacers 44 (see FIG. 11). In FIG. 14, only portions of the gate dielectric layer 62 that are formed on the ILs 61 and the isolation features 30 are shown. In some embodiments, the gate dielectric layer 62 includes or is made of a high dielectric constant material, but is not limited thereto. The gate dielectric layer 62 has a dielectric constant (k value) that is higher than a dielectric constant of each of the gate spacers 44, the CESLs 54, and ILDs 55 (see FIG. 11). A thickness of the gate dielectric layer 62 is less than a thickness of each of the gate spacers 44. The high dielectric constant material may be a dielectric material with wide band gap and good thermal stability. Examples of the high dielectric constant material are a hafnium-based dielectric material (e.g. hafnium oxide, hafnium aluminum oxide, hafnium silicon oxide), zirconium oxide, zirconium aluminum oxide, titanium oxide, yttrium oxide, magnesium oxide, calcium oxide, zirconium silicate, aluminum oxide, scandium oxide, or other suitable materials. In some other embodiments, the gate dielectric layer 62 includes or is made of silicon oxide, silicon nitride, silicon oxynitride or other low dielectric constant materials. In some embodiments, the gate dielectric layer 62 is formed using CVD, ALD (e.g., thermal ALD or plasma ALD), but are not limited thereto. Other suitable materials and/or processes for forming the gate dielectric layer 62 are within the contemplated scope of the present disclosure.

After forming the gate dielectric layer 62, a base structure is obtained. Step 101 in the flow diagram shown in FIG. 1 is exemplified by the structures shown in FIGS. 2 to 14.

The base structure includes a first region 901 and a second region 902 that are displaced from each other. The first region 901 and the second region 902 may be adjacent to (e.g., connected to) each other as shown in FIG. 14, but is not limited thereto. In other embodiments, the first region 901 and the second region 902 may be spaced apart from each other. In some embodiments, the first region 901 and the second region 902 may be used for forming devices with different conductivity types. In some other embodiments, the first region 901 and the second region 902 may be used for forming devices with the same conductivity type. In some embodiments, the first region 901 is an n-type region for forming an n-type device, and the second region 902 is a p-type region for forming a p-type device (or vice versa in some other embodiments).

At each of the first region 901 and the second region 902, one of the fins 12 and corresponding ones of the channel features 21′ (that originate from a same one of the stack portions 20′ (see FIG. 10)) are shown. The fin 12 and the corresponding channel features 21′ are spaced apart from each other in the Z direction. The corresponding channel features 21′ interconnect two corresponding ones of the source/drain features 53 (not shown in FIG. 14, see FIG. 9) in the X direction. Each of the channel features 21′ is surrounded by a corresponding one of the ILs 61 and a corresponding portion of the gate dielectric layer 62. The fin 12 is covered by a corresponding one of the ILs 61 and a corresponding portion of the gate dielectric layer 62.

The processes involved in forming a gate structure are described hereinafter. It is noted that materials used for forming the gate structure (e.g., work function metal, dipole material) may result in a portion of the gate structure formed at the first region 901 having an electrical property different from a portion of the gate structure formed at the second region 902. Thus, the following processes are performed by inclusion of different work function metals in the gate structure or by modifying the gate structure using one or more dipole layers.

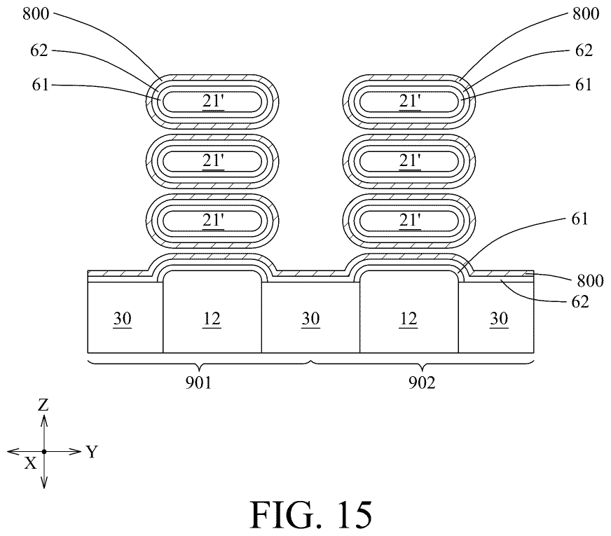

Referring to FIG. 15, an intermediate layer 800 is formed over the structure shown in FIG. 14.

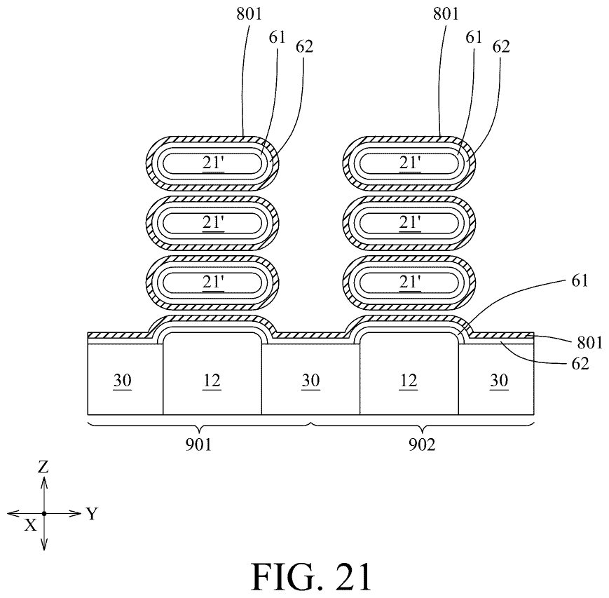

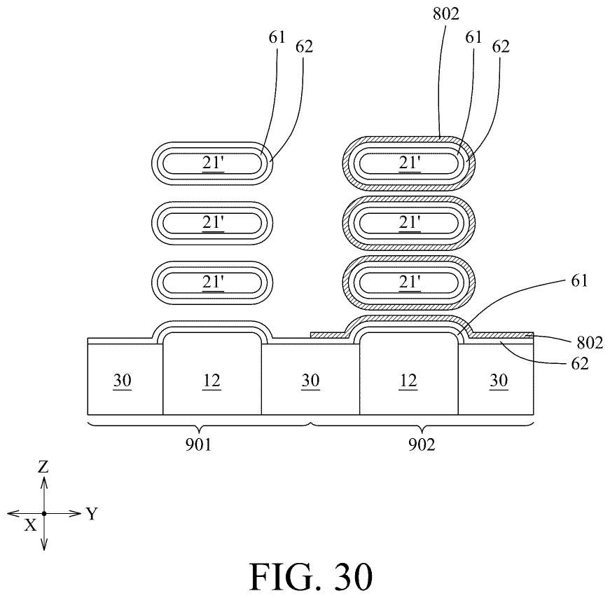

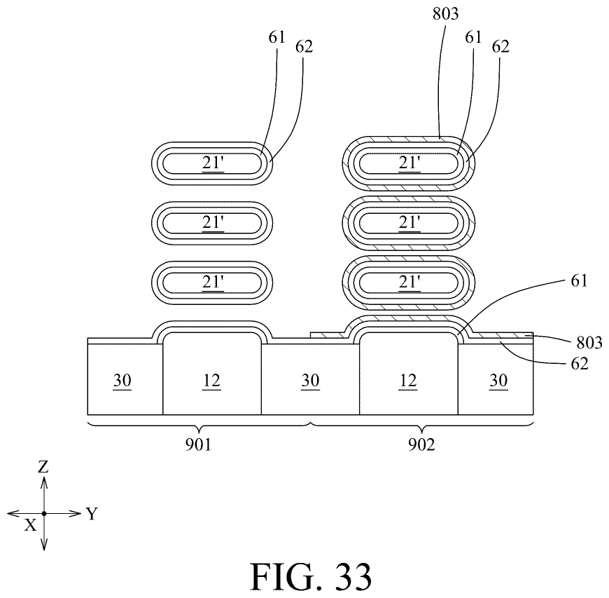

A first portion and a second portion of the intermediate layer 800 are respectively formed over the first region 901 and the second region 902. The intermediate layer 800 may include any suitable material that facilitates formation of the gate structure at the first region 901 and the second region 902. For instance, in some embodiments, the intermediate layer 800 may be a work function metal layer, which will be described in details with reference to FIGS. 21 to 29 hereinafter. In other embodiments, the intermediate layer 800 may be a dipole layer, which will be described in details with reference to FIGS. 30 to 32 hereinafter. In some other embodiments, the intermediate layer 800 may be a diffusion barrier layer, which will be described in details with reference to FIGS. 33 to 36 hereinafter. It should be noted that, the intermediate layer 800 may be a layer that remains in the final product, or may be a layer that serves a certain purpose in a certain step of the manufacturing process and that is to be removed from the final product. Accordingly, the intermediate layer 800 may include different materials, depending on application of the intermediate layer 800. Please note that the intermediate layer 800 is not limited to serve as the work function metal, the dipole layer or the diffusion barrier layer. Other suitable applications of the intermediate layer 800 are within the contemplated scope of the present disclosure.

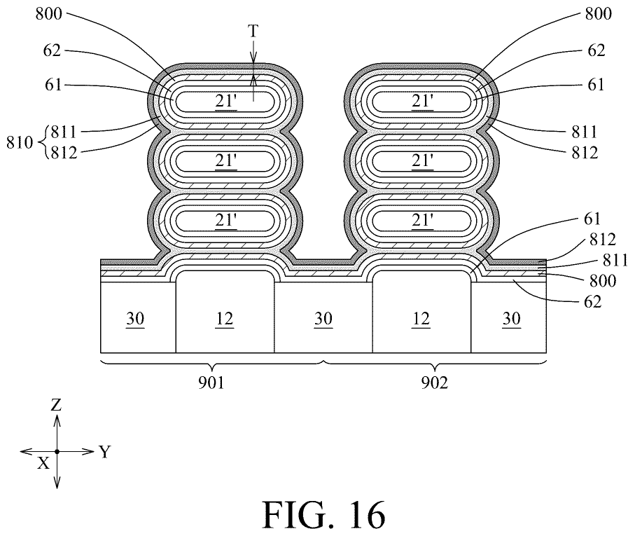

Referring to FIG. 16, a hard mask unit 810 is formed. The hard mask unit 810 has a first portion and a second portion which are respectively formed over the first region 901 and the second region 902. In the presence of the intermediate layer 800, the first portion and the second portion of the hard mask unit 810 are respectively formed over the first portion and the second portion of the intermediate layer 800. The step illustrated by FIG. 16 is also shown as step 102 in the flow diagram shown in FIG. 1.

In some embodiments, in the hard mask unit 810, each of the first portion and the second portion includes an inner layer 811 and an outer layer 812 that are sequentially formed over the intermediate layer 800 (and over the fins 12 and surrounding each of the channel features 21′). In some embodiments, as shown in FIG. 16, the inner layer 811 is formed not only to surround the channel features 21′, but also to fill spaces between adjacent ones of the channel features 21′ (that originate form the same one of the stack portion 20′, see also FIGS. 10 and 11), and between each of the fins 12 and a bottommost one of the corresponding channel features 21′.

The inner layer 811 and the outer layer 812 are made of different materials so that an etching rate of the inner layer 811 is very different from an etching rate of the outer layer 812 when the inner layer 811 and the outer layer 812 are subjected to a same etchant (e.g., a wet chemical or other suitable etchant).

In some embodiments, each of the inner layer 811 and the outer layer 812 may independently include or be made of silicon oxide, aluminum oxide, titanium nitride, titanium oxide, scandium oxide, yttrium oxide, lutetium oxide, lanthanum oxide, zinc oxide, strontium oxide, indium oxide, gallium oxide, erbium oxide, niobium oxide, silicon oxynitride, silicon nitride, polysilicon, amorphous silicon, a carbon-containing dielectric material, a nitride-containing dielectric material, a refractory metal or combinations, but are not limited thereto. In some embodiments, the inner layer 811 may include a material that is formed from a relatively small size precursor. Such relatively small size precursor could readily enter narrow gaps, for instance, spaces between adjacent channel features 21′, so that the material can better fill up the narrow gaps and avoids any void formation. Other suitable materials for forming the inner layer 811 and the outer layer 812 are within the contemplated scope of the present disclosure.

The hard mask unit 810 may be formed using an ALD process, such as a thermal ALD, or a plasma enhanced ALD, so as to minimize loading effect, and to conformally form ultra-thin films with superior quality. During the ALD process, water, oxygen or ozone may serve as an oxidizer. In some embodiments, the inner layer 811 is formed by a deposition process (e.g., an ALD process, but is not limited thereto) to form an inner material layer (not shown) over the intermediate layer 800, followed by a trimming process (e.g., any suitable etching process, but is not limited thereto) to remove an excess amount of the inner material layer, thereby forming the inner layer 811. The outer layer 812 may be formed by a deposition process (e.g., and ALD process, but is not limited thereto). Other suitable materials and/or processes for forming the inner layer 811 and the outer layer 812 are within the contemplated scope of the present disclosure.

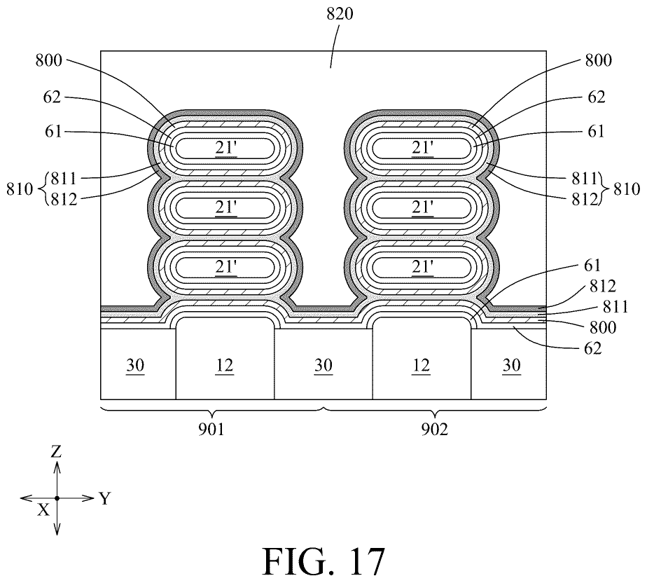

Referring to FIG. 17, a polymeric material layer 820 is formed over the hard mask unit 810 (covering both first portion and the second portion of the hard mask unit 810). In some embodiments, the polymeric material layer 820 includes or is made of a bottom anti-reflective coating (BARC) material, such as a polyvinylphenol or a polystyrene, but are not limited thereto. The polymeric material layer 820 may be formed by any suitable deposition process, such as CVD, ALD, and spin coating, but are not limited thereto. Other suitable materials and/or processes for forming the polymeric material layer 820 are within the contemplated scope of the present disclosure.

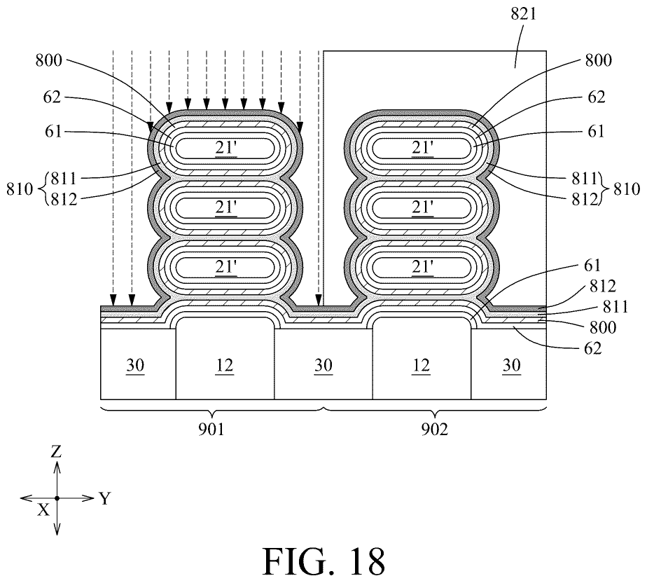

Referring to FIG. 18, a patterning process is performed to pattern the polymeric material layer 820 (see FIG. 17) into a patterned polymeric mask 821. In some embodiments, the patterning process may include an etching process, such as a plasma etching process, but is not limited thereto. During the plasma etching process (see the dotted arrows), a portion of the polymeric material layer that is located at the first region 901 is removed and a portion of the polymeric material layer that is located at the second region 902 remains to serve as the patterned polymeric mask 821. As such, after the patterning process, the first portion of the hard mask unit 810 is exposed from the patterned polymeric mask 821, whereas the second portion of the hard mask unit 810 remains covered by the patterned polymeric mask 821.

During removal of the portion of the polymeric material layer 820 at the first region 901, the channel features 21′, the fin 12, the corresponding portions of the gate dielectric layer 62, and the corresponding ILs 61 at the first region 901 are well protected by the first portion of the hard mask unit 810, such that these elements are not damaged by the plasma etching process and thus remain intact. In some embodiments, the hard mask unit 810 may have a thickness (T, see FIG. 16) ranging from about 2 nm to about 3 nm, so as to sufficiently and effectively protect the abovementioned elements at the first region, and especially the topmost one of the channel features 21'. If the hard mask unit 810 is too thick (e.g., greater than about 3 nm), removal or patterning of the hard mask unit 810 (e.g., removal of the first portion of the hard mask unit 810) may undesirably cause damage to other elements.

At the second region 902, the channel features 21′ are protected by the second portion of the hard mask unit 810 and shielded by the patterned polymeric mask 821, such that the channel features 21′ are not damaged by the plasmas etching process, and thus also remain intact. Step 103 in the flow diagram shown in FIG. 1 is exemplified by the structures shown in FIGS. 17 and 18.

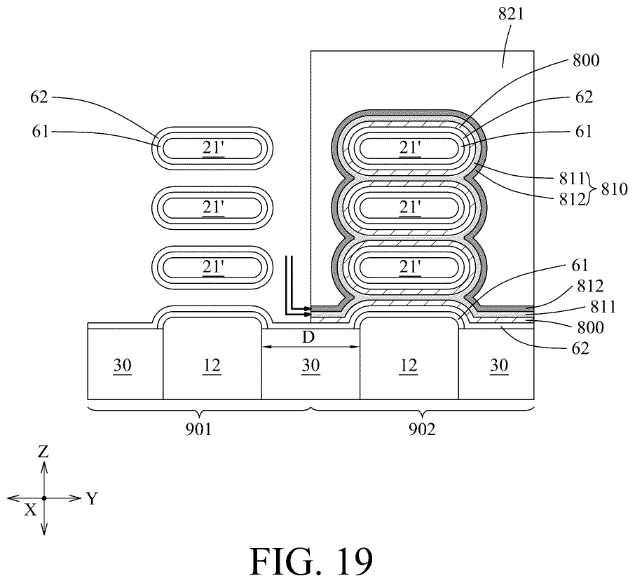

Referring FIG. 19, a first removing process is performed to remove the first portion of the hard mask unit 810 shown in FIG. 18 using an etching process or other suitable processes. Step 104 in the flow diagram shown in FIG. 1 is exemplified by the structure shown in FIG. 19. Afterward, the first portion of the intermediate layer 800 is also removed in the first removing process.

In some embodiments, in the etching process, the outer layer 812 and the inner layer 811 of the first portion of the hard mask unit 810 are sequentially removed using a first etchant and a second etchant, respectively. Each of the first and second etchants applied may include diluted hydrofluoric acid (dHF), deionized carbon dioxide (DICO₂), deionized water (DIW), deionized ozone (DIO₃), ammonium hydroxide (NH₄OH), hydrochloric acid (HCl), sulphuric acid (H₂SO₄), hydrogen peroxide (H₂O₂), other suitable etchants, and combinations thereof. The etchants are applied with different concentrations at different temperatures in accordance to the material(s) of each of the inner layer 811 and the outer layer 812, or based on practical needs, such that the inner layer 811 and the outer layer 812 are etched at different etching rates.

For instance, when the first etchant is applied to remove mainly the outer layer 812 at the first region 901, the outer layer 812 exhibits an etching rate that is at least about 80 times (e.g., about 80 times to about 100 times, or more than 100 times) higher than an etching rate of the inner layer 811. Therefore, the inner layer 811 at both the first region 901 and the second region 902, and any elements underneath, remain substantially intact.

Subsequently, when the second etchant is applied to remove mainly the inner layer 811 at the first region 901, the inner layer 811 exhibits an etching rate that is at least about 80 times (e.g., about 80 times to about 100 times, or more than 100 times) higher than an etching rate of the outer layer 812. As such, the outer layer 812 at the second region 902 is substantially not affected by the second etchant. In some embodiments, the inner layer 811 and the intermediate layer 800 also exhibit different etching rates upon application of the second etchant. For instance, when the second etchant is applied, the inner layer 811 may exhibit an etching rate that is at least about 80 times (e.g., about 80 times to about 100 times, or more than 100 times) higher an etching rate of the intermediate layer 800. After removing the first portion of the hard mask unit 810, the intermediate layer 800 at both the first region 901 and the second region 902, and any elements underneath, remain substantially intact.

The configuration of the multi-layered hard mask unit 810, and the layer-by-layer removal approach is beneficial in minimizing damage, if any, to the second portion of the hard mask unit 810 during removal of the first portion of the hard mask unit 810, without reducing the thickness of the hard mask unit 810 (which is crucial to protect the elements at the first region 901 in patterning of the polymeric material layer 820 as aforementioned).

In a case where the hard mask unit is a single-layer hard mask, (not shown in the figure, e.g., includes only the inner layer 811 or the outer layer 812 of the present disclosure), the single-layer hard mask should have a sufficient thickness for protecting elements underneath during patterning of the polymeric material layer 820. In such case, during removal of the first portion of the single-layer hard mask using an etchant, the second portion of the single-layer hard mask, especially a lateral sidewall of the second portion, is exposed and inevitably provides a relatively large window for the etchant to penetrate into, and is very likely to be damaged, since the first portion and the second portion are both made of the same material and both have a relatively thick thickness. That is, the etchant readily penetrates into and damages the second portion of the single-layer hard mask through the lateral sidewall of the second portion. Such single-layer hard mask may lose its function to protect elements at the second region, and causes the elements to be undesirably exposed to other subsequent processes. To avoid such circumstances, it is common to increase an OD-OD distance (D, ranging from about 20 nm to about 40 nm, or any other suitable range), which may refer to a distance between adjacent ones of the fins 12 that are respectively located at the first region 901 and the second region 902, so as to reduce penetration of the etchant into the second region 902 and to reduce damage of the elements (e.g., the channel features) at the second region 902. However, it is noted that a large OD-OD distance is unconducive in reducing critical dimensions of the semiconductor structure.

In contrast, in the present disclosure, the hard mask unit 810 may have the same thickness as of the case of single-layer hard mask discussed in previous paragraph. Such same thickness of the hard mask unit 810 includes the thickness of the inner layer 811 and the thickness of the outer layer 812. In some embodiments, a ratio of the thickness of the inner layer 811 to the thickness of the outer layer 812 may be approximately 1:1 (such as ranging from about 0.4:0.6 to about 0.6:0.4), but is not limited thereto, so that the hard mask unit 810 offers a better protection to the underlying elements. In certain embodiments, each of the inner layer 811 and the outer layer 812 may have a thickness ranging from about 0.5 nm to about 1.5 nm, such as about 0.5 nm to about 1.0 nm. Other suitable thickness ranges of the inner layer 811 and the outer layer 812 are within the contemplated scope of the present disclosure. The outer layer 812 and the inner layer 811 exhibit very different etching rates upon application of an etchant, and the outer layer 812 and the inner layer 811 are sequentially removed using different etchants. During removal of the outer layer 812 of the first portion using the first etchant, the lateral sidewall (thickness ranging, e.g., from about 0.5 nm to about 1.5 nm) of the outer layer 812 at the second region 902 accounts for merely a portion (e.g., approximately a half, but is not limited thereto) of the lateral sidewall (thickness) of the hard mask unit 810, and thus the window for the first etchant to penetrate into the outer layer 812 at the second region 902 is significantly reduced. In addition, the inner layer 811, which has an etching rate to the first etchant much lower than that of the outer layer 812, can further minimize damage to the second portion of the hard mask unit 810 (i.e., at least the inner layer 811 of the second portion is substantially unaffected by the first etchant). Similarly, during removal of the inner layer 811 of the first portion using the second etchant, the lateral sidewall (thickness) of the inner layer 811 at the second region 902 accounts for merely a portion of the lateral sidewall (thickness) of the hard mask unit 810, and thus the window for the second etchant to penetrate into the inner layer 811 at the second region 902 is significantly reduced. In addition, the outer layer 812 and the intermediate layer 800, which have an etching rate to the second etchant much lower than that of the inner layer 811, can further minimize damage to the second portion of the hard mask unit 810, and the intermediate layer 800. Therefore, by virtue of forming the hard mask unit 810 including the inner layer 811 and the outer layer 812 having different etching rates, different etchants are applied during removal of the inner layer 811 and the outer layer 812 of the first portion of the hard mask unit 810. In such sequential etching processes, damage to the second portion of the hard mask unit 810 is minimized. Moreover, the hard mask unit 810 can still be formed to be relatively thick so as to provide sufficient protection in formation of the patterned polymeric mask 821.

After removal of the first portion of the hard mask unit 810, the first portion of the intermediate layer 800 is removed using any etching processes or other suitable processes. As shown in FIG. 19, the remaining second portion of the intermediate layer 800 is referred to as an intermediate element 800. In some embodiments, when an etchant is applied for removing the first portion of the intermediate layer 800, the intermediate layer 800 exhibits an etching rate that is at least about 80 times (e.g., about 80 times to about 100 times, or more than 100 times) higher than an etching rate of each of the gate dielectric layer 62, the outer layer 812, and the inner layer 811. The etchant used for removing the first portion of the intermediate layer 800 is determined based on the material of the intermediate layer 800.

After removal of the first portion of the intermediate layer 800, at the first region 901, the channel features 21′ and the fin 12 are covered by the gate dielectric layer 62, without being covered by the intermediate layer 800, whereas at the second region 902, the channel features 21′ and the fin 12 are covered by the gate dielectric layer 62, the intermediate element 800, the second portion of the hard mask unit 810, and the patterned polymeric mask 821.

Referring FIG. 20, a second removing process is performed to remove the patterned polymeric mask 821 shown in FIG. 19 using any suitable processes (e.g., ashing processes, etching processes, or combinations thereof). Step 105 in the flow diagram shown in FIG. 1 is exemplified by the structure shown in FIG. 20. Afterwards, the second portion of the hard mask unit 810 is also removed in the second removing process. Other suitable processes for removing the patterned polymeric mask 821, and the second portion of the hard mask unit 810 are within the contemplated scope of the present disclosure. As shown in FIG. 20, at the first region 901, the gate dielectric layer 62 covering the channel features 21′ and the fin 12 is exposed, while at the second region 902, the intermediate element 800 covering the gate dielectric layer 62, the channel features 21′ and the fin 12 is exposed. The structure shown in FIG. 20 may be further subjected to other different processes based on practical needs and product designs.

The above description describes a general flow for forming the intermediate element 800 at merely the second region 902, so as to allow other subsequent processes to proceed. The following paragraphs describe how such flow may be utilized in various applications. It should be noted that the discussed applications are merely some of the exemplary embodiments. Other suitable applications, especially in the field of patterning or gate replacement, are within the contemplated scope of the present disclosure.

In some other embodiments, the intermediate feature 800 shown in FIG. 20 may be exemplified as a work function metal (WFM) feature that may be formed at the second region 902 with reference to FIGS. 21 to 29.

Referring to FIG. 21, a WFM layer 801 is formed over the structure shown in FIG. 14. The WFM layer 801 serves as an example of the intermediate layer 800 as described in FIG. 15, and may have a single or multi-layered structure.

Similar to the intermediate layer 800 as described in FIG. 15, the WFM layer 801 has a first portion and a second portion that are respectively formed over the first region 901 and the second region 902. Specifically, the first portion of the WFM layer 801 is formed on the gate dielectric layer 62 to surround each of the channel features 21′ and over the fin 12 at the first region 901. The second portion of the WFM layer 801 is formed on the gate dielectric layer 62 to surround each of the channel features 21′ and over the fin 12 at the second region 902.

The WFM layer 801 may include any suitable work function metal material, such as a metal material (e.g., tungsten (W), titanium (Ti), tantalum (Ta), aluminum (Al), or ruthenium (Ru)), a metal-containing nitride (e.g., titanium nitride (TiN), or tantalum nitride (TaN)), a metal-containing silicide (e.g., nickel silicide (NiSi)), a metal-containing carbide (e.g., tantalum carbide (TaC)), or combinations thereof. In some embodiments, the WFM layer 801 may include a work function metal of p-type devices, such as titanium nitride (TiN), tungsten nitride (WN), tungsten carbon nitride (WCN), molybdenum nitride (MoN), or combinations thereof. Other suitable materials for forming the WFM layer 801 are within the contemplated scope of the present disclosure.

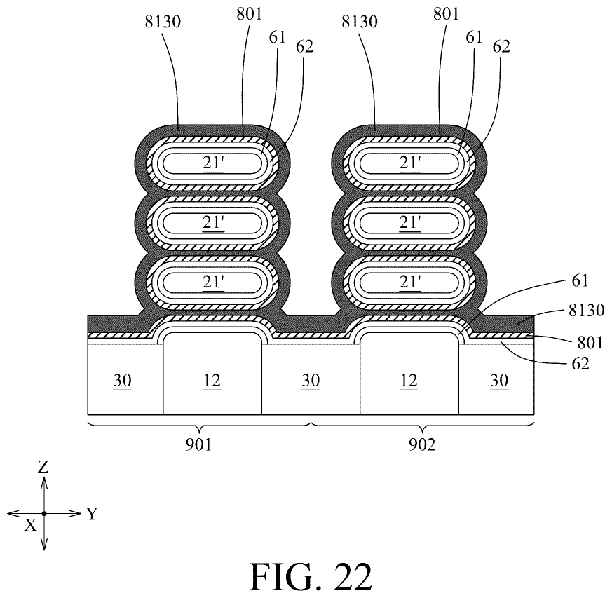

Referring to FIG. 22, an interposing material layer 8130 is formed over the WFM layer 801 using any suitable deposition processes. Examples of a material for forming the interposing material layer 8130 are similar to those of the inner layer 811 and/or the outer layer 812 as described in FIG. 16, and thus details thereof are omitted for the sake of brevity. In some embodiments, the interposing material layer 8130 is made of a material that is formed from a relatively small size precursor so as to better fill the spaces among the channel features 21′ and the fin 12.

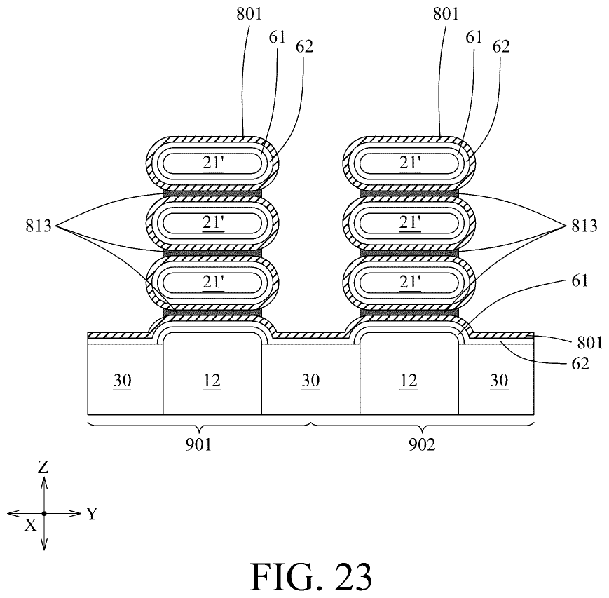

Referring to FIG. 23, a trimming process is performed to remove an excess amount of the interposing material layer 8130, thereby obtaining interposing layers 813. In some embodiments, the trimming process is an anisotropic etching process, such as a dry etching process. Other suitable trimming processes are within the contemplated scope of the present disclosure.

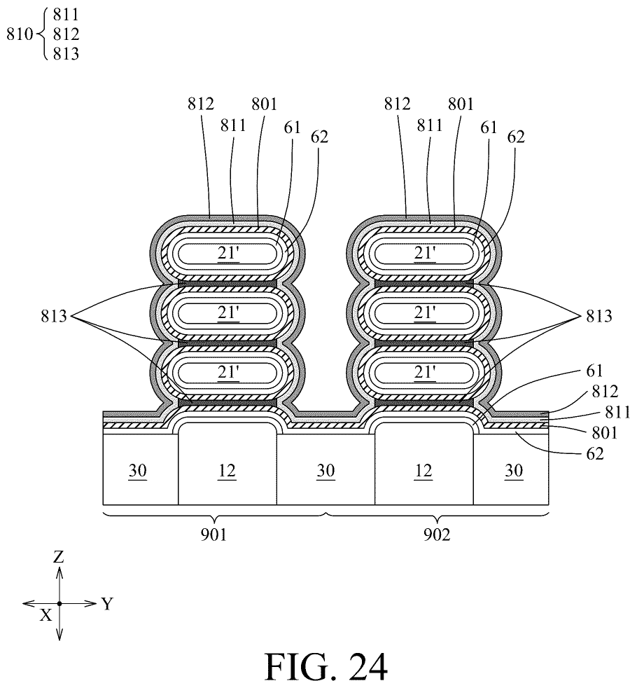

Referring to FIG. 24, an inner layer 811 and an outer layer 812 are sequentially formed over the structure shown in FIG. 23 in accordance with the manner described with reference to FIG. 16, thereby obtaining a hard mask unit 810 which includes the outer layer 812, the inner layer 811, and the interposing layers 813. Other suitable materials and/or processes for forming the hard mask unit 810 are within the contemplated scope of the present disclosure. Other details regarding the inner layer 811 and the outer layer 812 are similar to those described with reference to FIG. 16, and thus are omitted for the sake of brevity. Step 102 in the flow diagram shown in FIG. 1 is exemplified by the structures shown in FIGS. 22 to 24. The hard mask unit 810 shown in FIG. 24 is similar to the hard mask unit 810 shown in FIG. 16 except that the hard mask unit 810 shown in FIG. 24 further includes the interposing layers 813. Please note that the inclusion of the interposing layers 813 in the hard mask unit 810 is not limited to formation of WFM feature described hereinafter. One may freely decide to include the interposing layers 813 in the hard mask unit 810 or not based on practical needs. Similarly, the hard mask unit 810 shown in FIG. 24 has a first portion and a second portion which are respectively formed over the first portion and the second portion of the WFM layer 801.

In the hard mask unit 810 described in FIG. 16, at each of the first portion and the second portion, the inner layer 811 of the hard mask unit 810 fills the spaces between adjacent ones of the channel features 21′, and between the bottommost one of the channel features 21′ and the fin 12. In FIGS. 22 to 24, each of the first portion and the second portion further includes interposing layers 813 that respectively fill the spaces between adjacent ones of the channel features 21′, and between the bottommost one of the channel features 21′ and the fin 12. The inner layer 811 is formed to conformally cover the channel features 21′, the interposing layers 813, and the fin 12. The outer layer 812 is conformally formed over the inner layer 811.

In some embodiments, when an etchant is applied, the interposing layers 813 have an etching rate very different from the etching rate of each of the outer layer 812 and the inner layer 811.

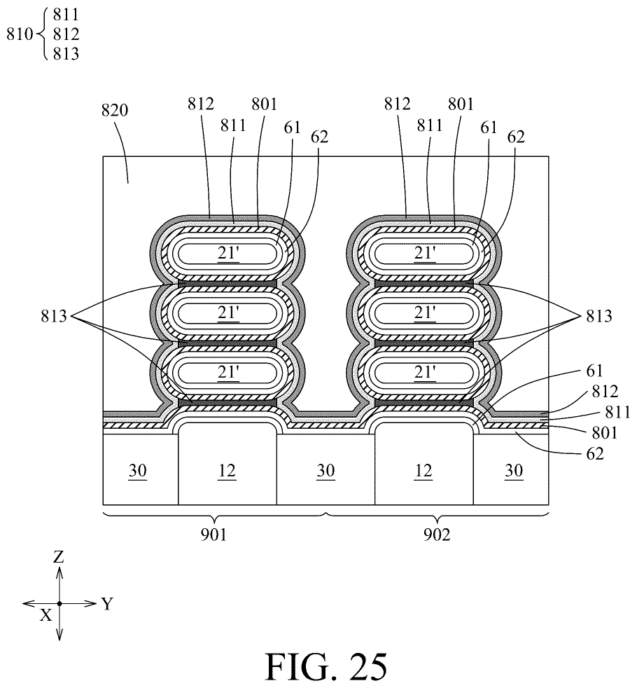

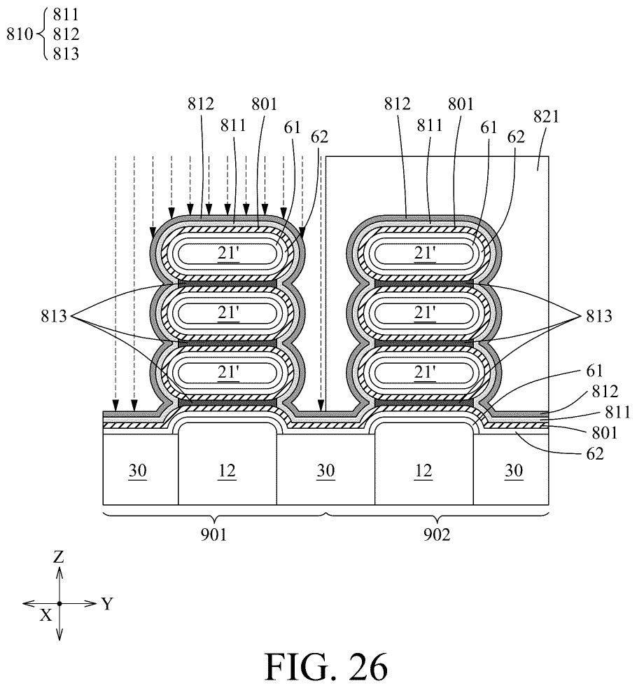

FIGS. 25 to 26 are respectively similar to FIGS. 17 to 18, but illustrating formation of a patterned polymeric mask 821 on the structure of FIG. 24 in accordance with some embodiments. Thus, step 103 in the flow diagram shown in FIG. 1 is also exemplified by the structures shown in FIGS. 25 and 26. Details of forming the patterned polymeric mask 821 are similar to those described with reference to FIGS. 17 and 18, and thus are omitted for the sake of brevity.

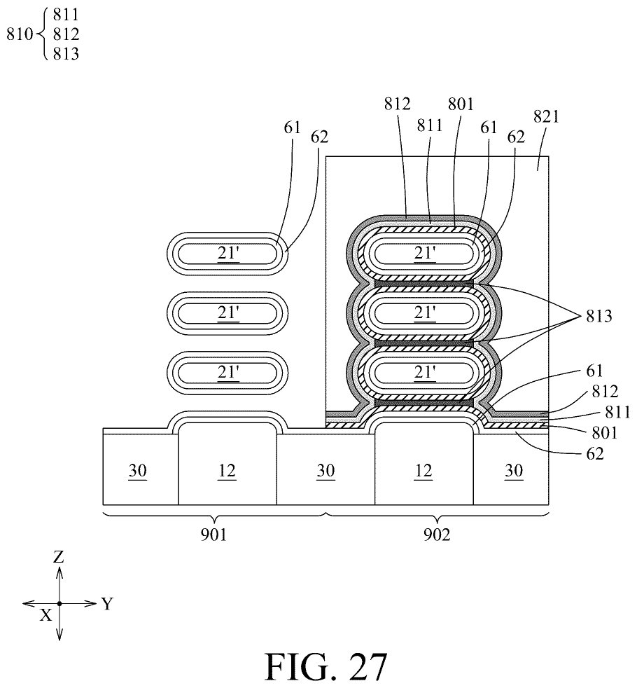

FIG. 27 is similar to FIG. 19, but illustrating the resultant structure after removal of the first portion of the hard mask unit 810 and the first portion of the WFM layer 801 on the structure of FIG. 26 in accordance with some embodiments. Thus, step 104 in the flow diagram shown in FIG. 1 is also exemplified by the structure shown in FIG. 27. As mentioned above, the WFM layer 801 may also refer to as the intermediate layer.

In some embodiments, the outer layer 812, the inner layer 811, and the interposing layers 813 of the first portion of the hard mask unit 810 are respectively removed using a first etchant, a second etchant, and a third etchant, respectively. In removing the outer layer 812 of the first portion, similar to that of FIG. 19, the first etchant is applied to remove mainly the outer layer 812 at the first region 901, and the etching rate of the outer layer 812 is at least about 80 times (e.g., about 80 times to about 100 times, or more than 100 times) higher than the etching rate of the inner layer 811. In removing the inner layer 811 of the first portion, similar to that of FIG. 19, the second etchant is applied to remove mainly the inner layer 811 at the first region 901, and the etching rate of the inner layer 811 is at least about 80 times (e.g., about 80 times to about 100 times, or more than 100 times) higher than both the etching rate of the outer layer 812 and the etching rate of the WFM layer 801. In removing the interposing layers 813 of the first portion, the third etchant is applied to remove mainly the interposing layers 813 at the first region 901. The interposing layers 813 exhibit an etching rate that is at least about 80 times (e.g., about 80 times to about 100 times, or more than 100 times) higher than an etching rate of each of the inner layer 811 and the outer layer 812. As such the third etchant substantially does not affect the inner layer 811 and the outer layer 812 of the second portion of the hard mask unit 810. That is, after removal of the first portion of the hard mask unit 810, the second portion of the hard mask unit 810 may remain substantially intact. In some embodiments, the etching rate of the interposing layers 813 may also be at least about 80 times (e.g., about 80 times to about 100 times, or more than 100 times) higher than an etching rate of the WFM layer 801, such that the WFM layer 801 at both the first region 901 and the second region 902, and any underlying elements, remain substantially intact.

Thereafter, the first portion of the WFM layer 801 is removed using any suitable processes. In some embodiments, the WFM layer 801 may exhibit an etching rate that is at least about 80 times (e.g., about 80 times to about 100 times, or more than 100 times) higher than an etching rate of each of the gate dielectric layer 62, the inner layer 811 and the outer layer 812. The remaining second portion of the WFM layer 801 is referred to as a WFM feature 801 that is formed merely at the second region 902, but not at the first region 901. In some embodiments, the WFM feature 801 is a p-type WFM formed at the second region 902 (on which a p-type device is to be formed), but not at the first region 901 (on which an n-type device or a p-type device is to be formed). In some embodiments, the WFM feature 801 is an n-type WFM formed at the second region 902 (on which an n-type device is to be formed), but not at the first region 901 (on which an n-type device or a p-type device is to be formed).

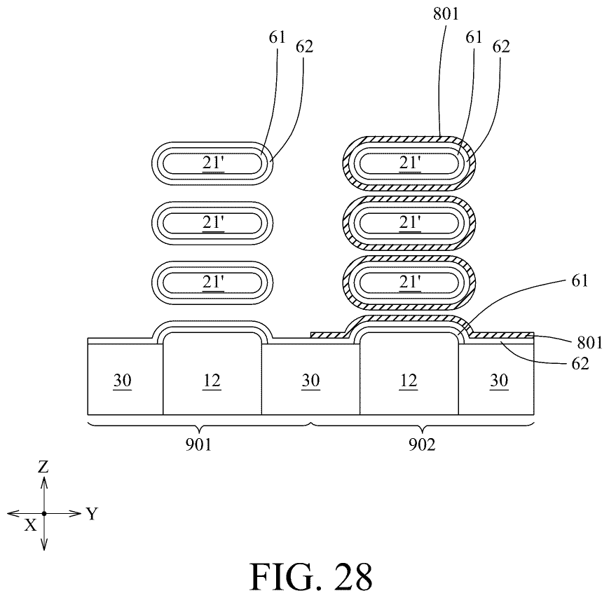

FIG. 28 is similar to FIG. 20, but illustrating a resultant structure after removal of the patterned polymeric mask 821, and the second portion of the hard mask unit 810 on the structure of FIG. 27 in accordance with some embodiments. Thus, step 105 in the flow diagram shown in FIG. 1 is also exemplified by the structure shown in FIG. 28. As shown in FIG. 28, at the first region 901, the gate dielectric layer 62 covering the channel features 21′ and the fin 12 is exposed, and at the second region 902, the WFM feature 801 covering the channel features 21′ and the fin 12 is exposed.

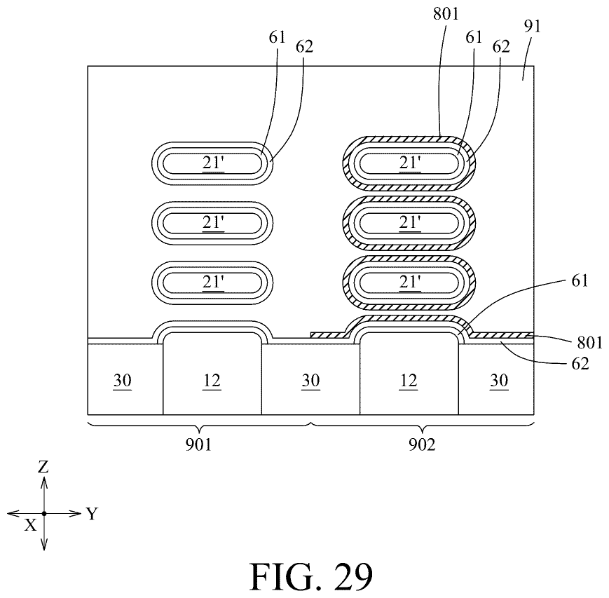

Referring to FIG. 29, another WFM feature 91 is formed over the structure shown in FIG. 28. Possible materials for the WFM feature 91 are similar to those for the WFM feature 801 except that the WFM feature 91 and the WFM feature 801 are made of different materials so that the devices formed on the first and second regions 902 may have different threshold voltages. In some embodiments, one of the WFM feature 91 and the WFM feature 801 is an n-type WFM, and the other one of the WFM feature 91 and the WFM feature 801 is a p-type WFM. In some embodiments, both the WFM feature 91 and the WFM feature 801 are the same type WFM, but are made of different materials. Examples of the p-type WFM have been discussed, and are not repeated. Examples of the n-type WFM include aluminum (Al), titanium aluminum carbide (TiAlC), titanium aluminum (TiAl), or combinations thereof, or other suitable materials. In some embodiments, the WFM feature 91 may be formed over the structure of FIG. 28 using any suitable deposition process to fill the cavity 47 shown in FIG. 11, followed by a planarization process (e.g., CMP) to expose the ILD 55 (see FIG. 11). By forming the WFM feature 91, the gate structure (including the gate dielectric layer 62, the WFM feature 91 and the WFM feature 801) is formed and is elongated in the Y direction. The gate structure includes a gate electrode (including the WFM feature 91 and the WFM feature 801), together with the gate dielectric layer 62, is formed along channel features 21′ and the isolation features 30. The gate electrode may have a seam (not shown) in a cross-section taken along the X direction, and the outmost profile of the gate electrode in the cross-section taken along the X direction is not linear. In some embodiments, an interface (not shown) between the gate structure and a corresponding one of the gate spacers 44 (see FIG. 11) is curved. The topmost surface of each of the isolation features 30 has a portion that intermixes at an interface between the gate structure and the each of the isolation features 30. Although the topmost surface of each of the isolation features 30 is a planer surface shown in FIG. 29, in some embodiments, the topmost surface is non-planar. Although the isolation features 30 have the same height in FIG. 29, in some embodiments, the isolation features 30 may have different heights, and thus the bottommost surfaces of the gate structure on different isolations features 30 may be at different levels. In some embodiments, at least one of the WFM features 91, 801 is a Ti-based material. Although the gate structure in FIG. 29 has a planar topmost surface, in some embodiments, the topmost surface of the gate structure is not planar. After formation of the gate structure, each of the gate spacers 44 (see FIG. 11) is formed between the gate dielectric layer 62 and a corresponding one of the CESLs 54 (one of which is shown in FIG. 11). In some embodiments, at the first region 901, a gate electrode of the gate structure includes the WFM feature 91, while at the second region 902, the gate electrode include the WFM feature 801, and the WFM feature 91 covering the WFM feature 801.

In some embodiments, prior to forming a gate electrode (which may be formed to include one or more work function materials), dipole layer(s) may be formed over the gate dielectric layer 62, in which the dipole layer(s) provide a source of dipole elements that diffuse into the gate dielectric layer 62, so as to fine tune threshold voltage of the gate electrode at different regions (e.g., the first and second regions 901, 902). For instance, a dipole feature 802 (see FIG. 30) may be formed at the second region 902 in steps 102 to 105 in the flow diagram shown in FIG. 1 which are described hereinafter with reference to FIGS. 14 to 20.

A dipole layer (not shown, which may have a single or multi-layered structure) is formed over the structure shown in FIG. 14 using any suitable deposition processes. The dipole layer, exemplifying the intermediate layer 800 shown in FIG. 15, is formed in the same position as the intermediate layer 800. In some embodiments, the dipole layer includes p-type dipole elements, such as zinc (Zn), gallium (Ga) aluminum (Al), titanium (Ti), niobium (Nb), scandium (Sc) or combinations thereof, but are not limited thereto. In some embodiments, the dipole layer includes n-type dipole elements, such as lanthanum (La), magnesium (Mg), yttrium (Y), strontium (Sr), or combinations thereof. In some embodiments, the dipole layer may include or be made of lanthanum oxide, yttrium oxide, scandium oxide, lutetium oxide, or combinations thereof. Other suitable materials for forming the dipole layer are within the contemplated scope of the present disclosure.

Referring to FIG. 1, in step 102, a hard mask unit 810 (see FIG. 16) is formed over the dipole layer (which is in the same position as the intermediate layer 800 shown in FIG. 16) in accordance with the manner described with reference to FIG. 16.

Referring to FIG. 1, in step 103, the patterned polymeric mask 821 is formed over the second portion of the hard mask unit 810 in accordance with the manner described with reference to FIGS. 17 and 18.

Referring to FIG. 1, in step 104, the first portion of the hard mask unit 810 (see FIG. 18) and a first portion of the dipole layer (which is in the same position as the first portion of the intermediate layer 800 shown in FIG. 18) are removed in accordance with the manner described with reference to FIG. 19. The remaining second portion of the dipole layer is referred to as the dipole feature 802 shown in FIG. 30. In some embodiments, the dipole feature 802 may serve as a source for p-type dipole elements or n-type dipole elements that diffuse into the gate dielectric layer 62 of the second region 902 (for forming a p-type or n-type device thereon).

Referring to FIG. 1, in step 105, the patterned polymeric mask 821, and the second portion of the hard mask unit 810 shown in FIG. 19 are removed in accordance with the manner described with reference to FIG. 20. The resultant structure after completing step 105 is shown in FIG. 30. Referring to FIG. 30, at the first region 901, the gate dielectric layer 62 covering the channel features 21′ and the fin 12 is exposed, and at the second region 902, the dipole feature 802 covering the gate dielectric layer 62, the channel features 21′ and the fin 12 is exposed.

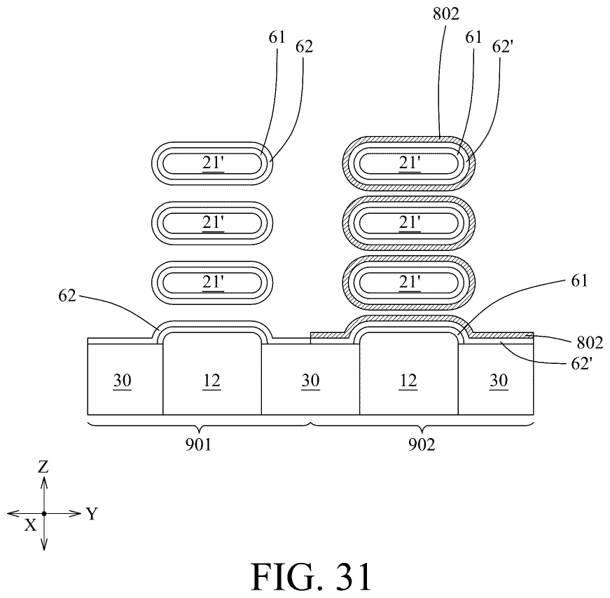

Thereafter, referring to FIG. 31, a dipole drive-in process (e.g., an annealing process or other suitable processes) is performed, such that dipole elements in the dipole feature 802 diffuse into parts of the gate dielectric layer 62 that are located at the second region 902 (see FIG. 30). The parts of the gate dielectric layer including the dipole elements are denoted by the numeral 62′ in FIG. 31. Parameters and operating conditions for the dipole drive-in process may be adjusted according to practical needs.

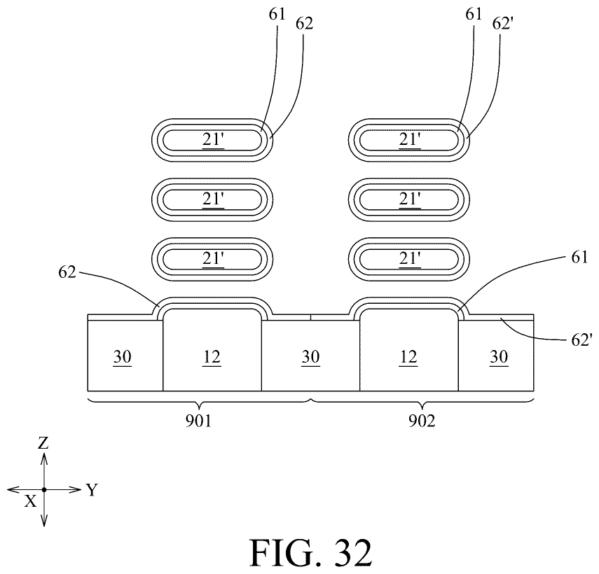

Referring to FIG. 32, the dipole feature 802 shown in FIG. 31 is then removed using any etching processes or other suitable processes. After removing the dipole features 802, the resultant structure shown in FIG. 32 has the parts of the gate dielectric layer 62′ at the second region 902 that are introduced with the dipole elements from the dipole feature 802, and another parts of the gate dielectric layer 62 at the first region 901 that are not introduced with any dipole elements. The resultant structure may be subjected to further processes based on practical needs or product designs, e.g., forming a gate electrode including one or multiple work function metals, but is not limited thereto.

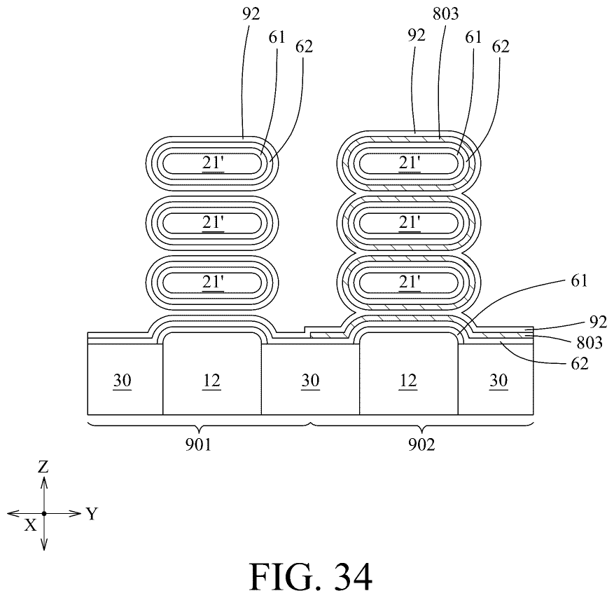

In some other embodiments, a dipole layer 92 (see FIG. 34) may be formed to selectively introduce dipole elements into the gate dielectric layer 62 at the first region 901. Prior to forming the dipole layer 92, a diffusion barrier feature 803 (see FIG. 33) is formed at the second region 902 with reference to FIGS. 14 to 28.

A diffusion barrier layer (not shown) is formed over the structure shown in FIG. 14 using any suitable deposition processes. In some embodiments, the diffusion barrier layer, exemplifying the intermediate layer 800 shown in FIG. 15, is formed in the same position as the intermediate layer 800. In some other embodiments, the diffusion barrier layer may be formed in the same position as the WFM layer 801 shown in FIG. 21. The diffusion barrier layer, which is to be formed into the diffusion barrier feature 803 shown in FIG. 33, may include a material that blocks penetration of any dipole elements therethrough, and that is chemically and thermally stable throughout a dipole drive-in process (e.g., an annealing process or other suitable processes). In some embodiments, the diffusion barrier layer includes an oxide, a nitride, a carbide, an oxynitride, an oxycarbide, a carbonitride, an oxycarbonitride, a metal oxide, a metal nitride, a metal carbide, a metal oxynitride, or combinations thereof. Examples of the materials for forming the diffusion barrier layer are silicon oxide, silicon nitride, aluminum oxide, aluminum nitride, titanium nitride, silicon oxynitride, silicon carbide, silicon oxycarbide, but are not limited thereto. Other suitable materials for forming the diffusion barrier layer are within the contemplated scope of the present disclosure.

Referring to FIG. 1, in step 102, a hard mask unit 810 (see FIG. 16 or 24) is formed over the diffusion barrier layer (which is in the same position as the intermediate layer 800 shown in FIG. 16 or the first portion of the WFM layer 801 shown in FIG. 24) in accordance with the manner described with reference to FIG. 16, or the manner described with reference to FIGS. 22 to 24.

Referring to FIG. 1, in step 103, the patterned polymeric mask 821 is formed over the second portion of the hard mask unit 810 in accordance with the manner described with reference to FIGS. 17 and 18 or the manner described with reference to FIGS. 25 and 26.

Referring to FIG. 1, in step 104, the first portion of the hard mask unit 810 (at the first region 901 shown in FIG. 17 or 25) and a first portion of the diffusion barrier layer (which is in the same position as the first portion of the intermediate layer 800 at the first region 901 shown in FIG. 17 or the first portion of the WFM layer 801 at the first region 901 shown in FIG. 25) are removed in accordance with the manner described with reference to FIG. 19, or the manner described with reference to FIG. 27. The remaining second portion of the diffusion barrier layer is referred to as the diffusion barrier feature 803 (see FIG. 33).

Referring to FIG. 1, in step 105, the patterned polymeric mask 821, and the second portion of the hard mask unit 810 (see FIG. 19 or 27) are removed in accordance with the manner described with reference to FIG. 20, or the manner described with reference to FIG. 28. The resultant structure after completing step 105 is shown in FIG. 33. After completing step 105, at the first region 901, the gate dielectric layer 62 covering the channel features 21′ and the fin 12 is exposed, and at the second region 902, the diffusion barrier feature 803 covering the gate dielectric layer 62, the channel features 21′ and the fin 12 is exposed.

Thereafter, referring to FIG. 34, the dipole layer 92 is formed over the structure shown in FIG. 33. Specifically, the dipole layer 92 is formed to conformally cover the gate dielectric layer 62 at the first region 901, and the diffusion barrier feature 803 at the second region 902. Possible materials for forming the dipole layer 92 are similar to those for forming the above dipole layer (i.e., the dipole feature 802 shown in FIG. 30), and thus the details thereof are omitted for the sake of brevity.

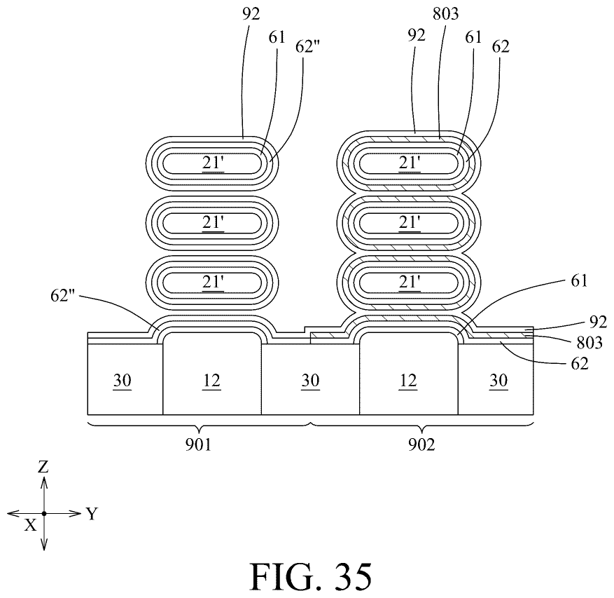

Referring to FIG. 35, a dipole drive-in process (e.g., an annealing process or other suitable processes) is then performed, such that dipole elements in the dipole layer 92 diffuse into parts of the gate dielectric layer 62 (see also FIG. 34) that are located at the first region 901. Parameters and operating conditions for the dipole drive-in process may be adjusted according to practical needs. At the second region 902, the diffusion barrier feature 803 may serve as a barrier to prevent any of the dipole elements diffusing from the dipole layer 92 into another parts of the gate dielectric layer 62 that are located at the second region 902. After the dipole drive-in process, the parts of the gate dielectric layer that receives the dipole elements is denoted by the numeral 62″ in FIG. 35.

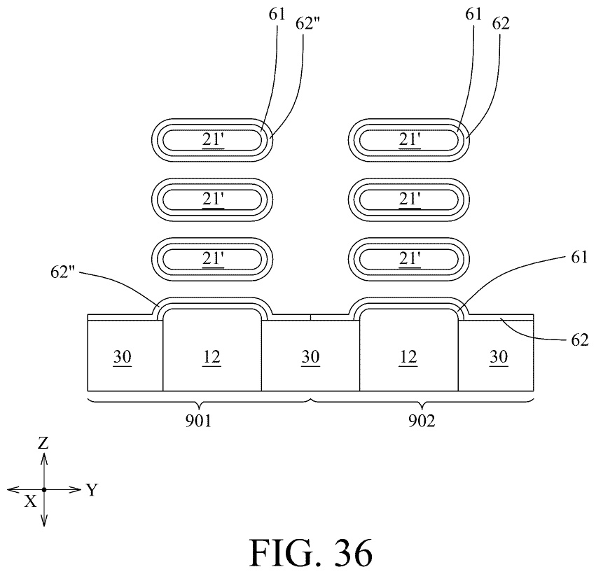

Referring to FIG. 36, the dipole layer 92 and the diffusion barrier feature 803 are removed using any etching processes or other suitable processes. After removing the dipole layer 92 and the diffusion barrier feature 803, the resultant structure shown in FIG. 36 has the parts of the gate dielectric layer 62″ at the first region 901 that are introduced with the dipole elements from the dipole layer 92, and another parts of the gate dielectric layer 62 at the second region 902 that are less likely to be introduced with the n-type dipole elements from the dipole layer 92. The resultant structure may be subjected to further processes based on practical needs or product designs, e.g., forming a gate electrode including one or multiple work function metals, but is not limited thereto.

FIGS. 15 to 36 illustrate, in accordance with some embodiments, that the intermediate layer 800 (e.g. the WFM layer 801, the dipole feature 802, the diffusion barrier feature 803) is formed prior to formation of the hard mask unit 810 (i.e., prior to step 102). In such case, the hard mask unit 810, or more specifically the second portion of the hard mask unit 810, is configured to protect the second portion of the intermediate layer 800 during removal of the first portion of the intermediate layer 800.

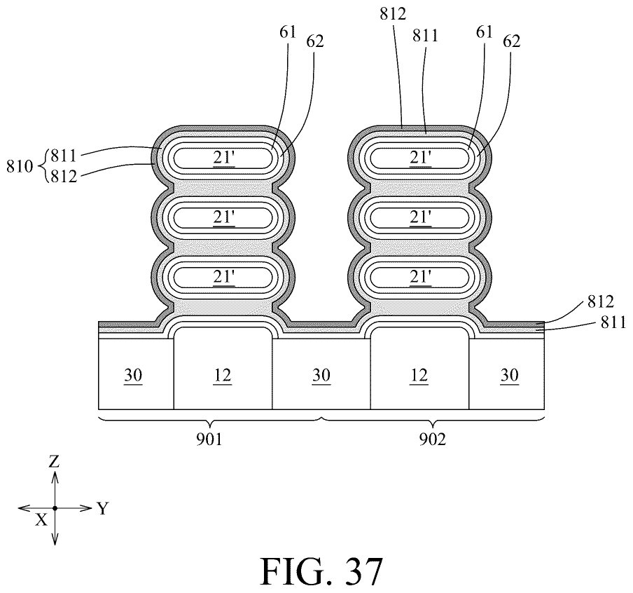

FIGS. 37 to 44 show steps subsequent to FIG. 14, illustrating in accordance with some other embodiments, where the intermediate layer 800 is formed after removing the first portion of the hard mask unit 810 and removing of the patterned polymeric mask 821 (i.e., after step 104 and 105).

Referring to FIG. 37, in step 102, the hard mask unit 810 is formed directly onto the base structure shown in FIG. 14. The first portion of the hard mask unit 810 is formed over and in direct contact with the first region 901, and the second portion of the hard mask unit 810 is formed over an in direct contact with the second region 902. Other details regarding step 102 are similar to those described in FIG. 16, and thus are not repeated for the sake of brevity.

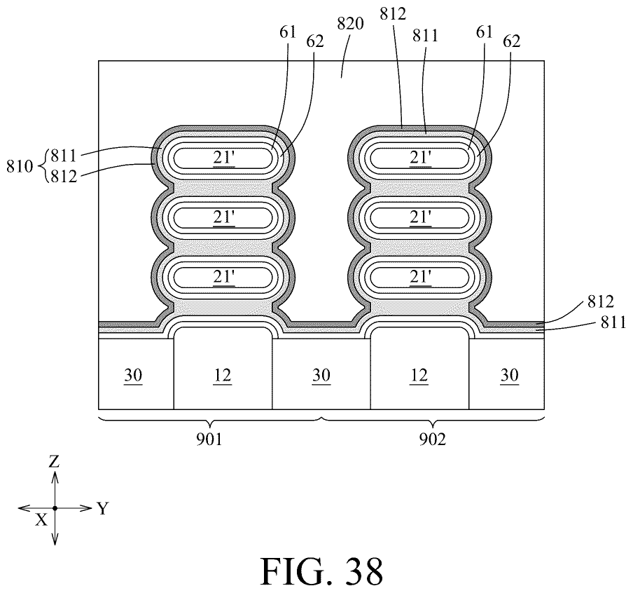

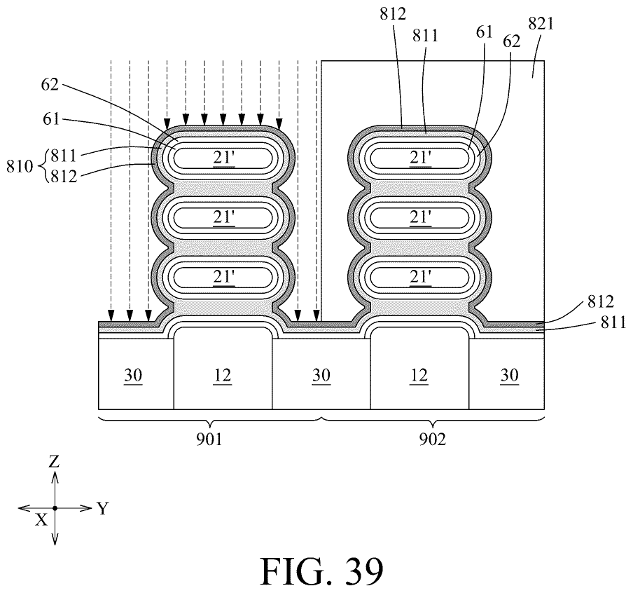

Referring to FIGS. 38 and 39, similar to FIGS. 17 and 18, in step 103, the polymeric material layer 820 is first formed over the hard mask unit 810, and is then patterned into the patterned polymeric mask 821. Other details regarding step 103 are similar to those described in FIGS. 17 and 18, and thus are not repeated for the sake of brevity.

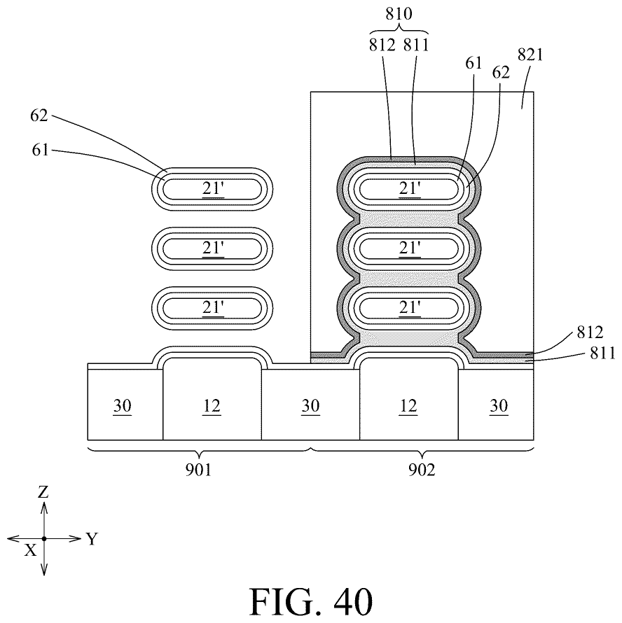

Referring to FIG. 40, in step 104, the first portion of the hard mask unit 810 shown in FIG. 39 is removed, such that the gate dielectric layer 62 surrounding the channel features 21′ at the first region 901 is exposed. Other details regarding step 104 are similar to those described in FIG. 19, and thus are not repeated for the sake of brevity.

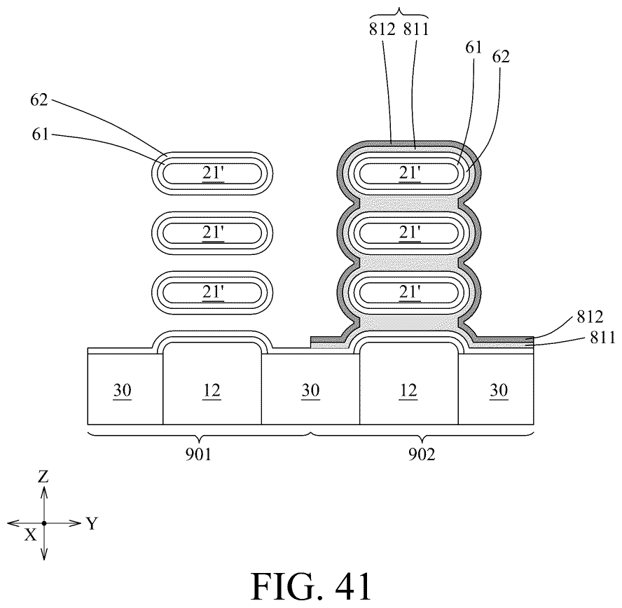

Referring to FIG. 41, in step 105, the patterned polymeric mask 821 is removed. Please note that, different from FIG. 20, in the exemplary embodiments shown in FIG. 41, the second portion of the hard mask unit 41 remains covering the second region 902. Other details regarding step 105 are similar to those described in FIG. 20, and thus are not repeated for the sake of brevity.

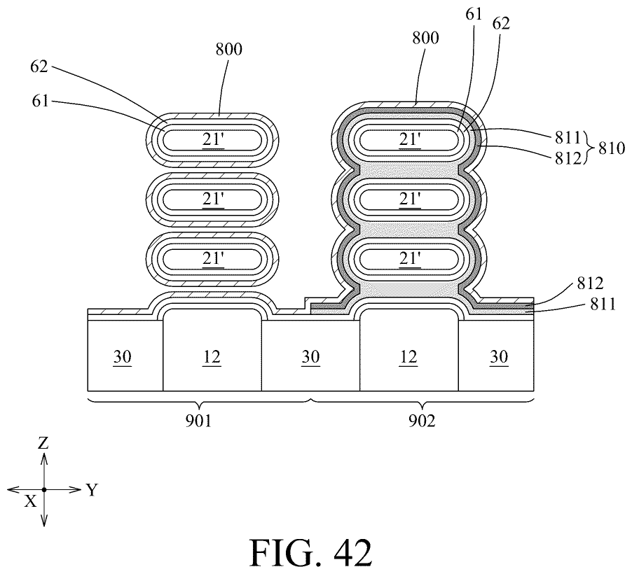

Referring to FIG. 42, the intermediate layer 800 is formed over the structure shown in FIG. 40. That is, the first portion of the intermediate layer 800 is formed over and in direct contact with the first region 901 to cover the gate dielectric layer 62; while the second portion of the intermediate layer 800 is formed over the second region 902 to cover and in direct contact with the second portion of the hard mask unit 810. The second hard mask unit 810 may serve as a barrier to prevent the second portion of the intermediate layer 800 being directly formed over the gate dielectric layer 62 at the second region 902. As described with reference to FIG. 15, the intermediate layer 800 may include any suitable material that facilitates formation of the gate structures at the first region 901 and the second region 902. In some embodiments, the intermediate layer 800 in FIG. 42 is a dipole layer. The dipole layer may include the n-type dipole elements or the p-type dipole elements as aforementioned, and are not repeated for the sake of brevity.

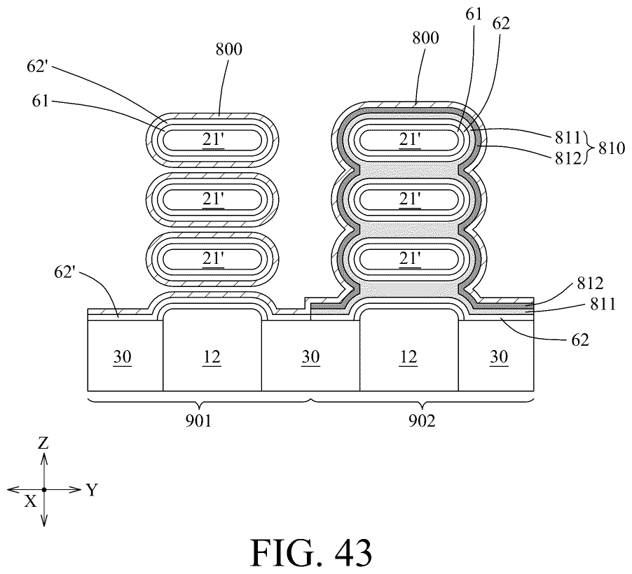

In some embodiments, when the intermediate layer 800 is the dipole layer, referring to FIG. 43, a dipole drive-in process (e.g., an annealing process or other suitable processes) is performed, such that the dipole elements diffuse into the parts of the gate dielectric layer (denoted by the numeral 62′) that are located at the first region 901. It is noted that the second portion of the hard mask unit 810 prevents the diffusion of the dipole elements into the gate dielectric layer 62 at the second region 902, and thus remaining parts of the gate dielectric layer 62 that are located at the second region 902 are not unaffected.

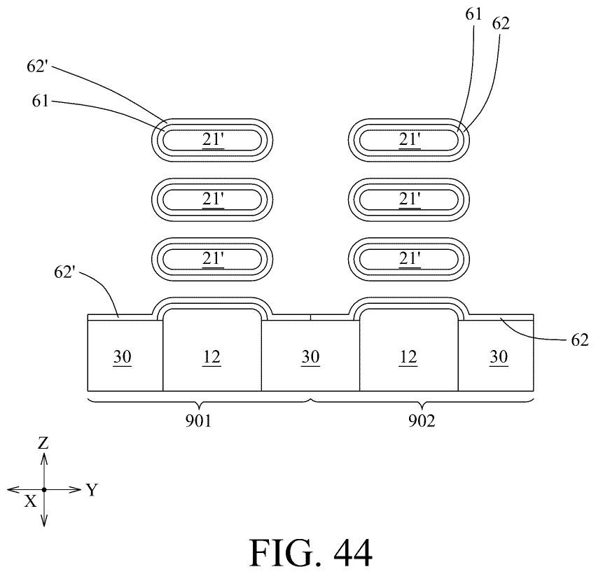

Referring to FIG. 44, after the dipole drive-in process, the dipole layer (i.e., the intermediate layer 800 shown in FIG. 43) is removed using any suitable process. In addition, the second portion of the hard mask unit 810 is removed to expose the remaining parts of the gate dielectric layer 62 located at the second region 902.

From FIGS. 37 to 44, where the intermediate layer 800 is formed after removing the first portion of the hard mask unit 810 and the patterned polymeric mask 821, the hard mask unit 810 is configured to expose the first region 901 (by removing the first portion of the hard mask unit 810) and to mask the second region 902. As such, the intermediate layer 800 formed subsequently is to be, in direct contact with the first region 901, and separated from the second region 902 by the remaining second portion of the hard mask unit 810. The resultant structure may be subjected to further processes based on practical needs or product designs, e.g., forming a gate electrode including one or multiple work function metals, but is not limited thereto.

In some other embodiments, the intermediate layer 800 may also be a work function metal, or other suitable material, or any other element that vary electrical properties of the gate structures of the different devices formed in the first region 901 and the second region 902.

The embodiments of the present disclosure have the following advantageous features. The hard mask unit 810 is formed with a thickness that provides sufficient protection to elements underneath during patterning of the polymeric mask. In addition, the outer layer 812 and the inner layer 811 of the hard mask unit 810, when subjected to an etching process using the same etchant, exhibit different etching rates. During removal of the first portion of the hard mask unit 810, the outer layer 812 and the inner layer 811 of the first portion are sequentially removed using different etchants. When one of the inner layer 811 and the outer layer 812 is removed using an etchant, another one of the inner layer 811 and the outer layer 812 is substantially unaffected, thereby reducing the window for the etchant to penetrate into the second portion of the hard mask unit 810. As such, the spacing between the different regions 901, 902 may be reduced, which facilitates reduction of critical dimension of the semiconductor structure.

In accordance with some embodiments of the present disclosure, a method for manufacturing a semiconductor structure includes: forming a base structure having a first region and a second region displaced from the first region; forming a hard mask unit, the hard mask unit having a first portion and a second portion which are respectively formed on the first region and the second region, each of the first portion and the second portion of the hard mask unit including an inner layer and an outer layer that are sequentially formed on the base structure and that are made of different materials; forming a patterned polymeric mask over the second portion of the hard mask unit, the first portion of the hard mask unit being exposed from the patterned polymeric mask; after forming the patterned polymeric mask, performing a first removing process to remove the first portion of the hard mask unit ; and after the first removing process, performing a second removing process to remove the patterned polymeric mask.

In accordance with some embodiments of the present disclosure, the first removing process includes: applying a first etchant to remove the outer layer of the first portion of the hard mask unit; and applying a second etchant that is different from the first etchant to remove the inner layer of the first portion of the hard mask unit.

In accordance with some embodiments of the present disclosure, when the first etchant is applied, the outer layer exhibits an etching rate that is at least 80 times higher than an etching rate of the inner layer.

In accordance with some embodiments of the present disclosure, when the second etchant is applied, the inner layer exhibits an etching rate that is at least 80 times higher than an etching rate of the outer layer.

In accordance with some embodiments of the present disclosure, each of the inner layer and the outer layer independently includes silicon oxide, aluminum oxide, titanium nitride, titanium oxide, scandium oxide, yttrium oxide, lutetium oxide, lanthanum oxide, zinc oxide, strontium oxide, indium oxide, gallium oxide, erbium oxide, niobium oxide, silicon oxynitride, silicon nitride, polysilicon, amorphous silicon, a carbon-containing dielectric material, a nitride-containing dielectric material, a refractory metal, or combinations thereof.

In accordance with some embodiments of the present disclosure, the protection mask unit has a thickness that ranges from 2 nm to 3 nm.

In accordance with some embodiments of the present disclosure, each of the inner layer and the outer layer has a thickness that ranges from 0.5 nm to 1.5 nm.

In accordance with some embodiments of the present disclosure, a method for manufacturing a semiconductor structure includes: forming a base structure having a first region and a second region displaced from the first region; forming a hard mask unit, the hard mask unit having a first portion and a second portion which are respectively formed on the first region and the second region, each of the first portion and the second portion of the hard mask unit including an inner layer and an outer layer that are sequentially formed on the base structure; forming a patterned polymeric mask over the second portion of the hard mask unit, the first portion of the hard mask unit being exposed from the patterned polymeric mask; after forming the patterned polymeric mask, performing a first removing process to sequentially remove the outer layer and the inner layer of the first portion of the hard mask unit; and after the first removing process, performing a second removing process to remove the patterned polymeric mask.

In accordance with some embodiments of the present disclosure, in the first removing process, when a first etchant is applied to remove the outer layer of the first portion of the hard mask unit, the outer layer exhibits an etching rate that is at least 80 times higher than an etching rate of the inner layer, and when a second etchant is applied to remove the inner layer of the first portion of the hard mask unit, the inner layer exhibits an etching rate that is at least 80 times higher than an etching rate of the outer layer.

In accordance with some embodiments of the present disclosure, after the second removing process, the first region of the base structure and the second portion of the hard mask unit are exposed, and the method further includes, after the second removing process, forming an intermediate layer which has a first portion and a second portion, the first portion of the intermediate layer being formed over the first region of the base structure, and the second portion of the intermediate layer being formed over the second portion of the hard mask unit.

In accordance with some embodiments of the present disclosure, each of the first region and the second region of the base structure includes channel features, and a gate dielectric layer having multiple portions that are respectively formed around the channel features; the intermediate layer is a dipole layer, the method further including: performing a dipole drive-in process, dipole elements in the dipole layer diffusing into the gate dielectric layer at the first region, the second portion of the hard mask unit preventing diffusion of the dipole elements into the gate dielectric layer at the second region; and removing the dipole layer after performing the dipole drive-in process.

In accordance with some embodiments of the present disclosure, the method further including, removing the second portion of the hard mask unit after removing the dipole layer.

In accordance with some embodiments of the present disclosure, before forming the hard mask unit, the method further including, forming an intermediate layer which has a first portion and a second portion that are respectively formed over the first region and the second region, the hard mask unit being formed over the intermediate layer, in the first removing process, a first portion of the intermediate layer exposed from the patterned polymeric mask being removed after removing the outer layer and the inner layer of the first portion of the hard mask unit, and in the second removing process, after removing the patterned polymeric mask, the second portion of the hard mask unit being removed to leave the second portion of the intermediate layer as an intermediate element.

In accordance with some embodiments of the present disclosure, each of the first region and the second region of the base structure includes channel features, and a gate dielectric layer having multiple portions that are respectively formed around the channel features; and the intermediate element is formed to cover the gate dielectric layer at the second region.

In accordance with some embodiments of the present disclosure, the intermediate element is a first work function metal feature, and the method further includes, after removing the patterned polymeric mask and the second portion of the hard mask unit, forming a second work function metal feature over the first region and the second region, a material of the first work function metal feature being different from a material of the second work function metal feature.

In accordance with some embodiments of the present disclosure, the intermediate feature is a dipole feature, and the method further includes, after removing the patterned polymeric mask and the second portion of the hard mask unit: performing a dipole drive-in process such that dipole elements in the dipole feature diffuse into the gate dielectric layer at the second region; and after the dipole drive-in process, removing the dipole feature.

In accordance with some embodiments of the present disclosure, the intermediate layer is a diffusion barrier feature, and the method further includes, after removing the patterned polymeric mask and the second portion of the hard mask unit: forming a dipole layer over the first region and the second region; performing a dipole drive-in process such that dipole elements in the dipole layer diffuse into the gate dielectric layer at the first region, penetration of the dipole elements in the dipole layer into the gate dielectric layer at the second region being blocked by the diffusion barrier feature; and after the dipole drive-in process, removing the dipole layer and the diffusion barrier feature.

In accordance with some embodiments of the present disclosure, a method for manufacturing a semiconductor structure includes forming a base structure on a substrate, the base structure having a first region and a second region displaced from the first region, each of the first region and the second region including: two source/drain features formed on the substrate; and channel features that are spaced apart from each other in a vertical direction and that interconnect the two source/drain features; forming a hard mask unit, the hard mask unit having a first portion and a second portion which are respectively formed on the first region and the second region, each of the first portion and the second portion of the hard mask unit including an inner layer and an outer layer that are sequentially formed on the channel features and that are made of different materials; forming a patterned polymeric mask over the second portion of the hard mask unit, the first portion of the hard mask unit being exposed from the patterned polymeric mask; after forming the patterned polymeric mask, performing a first removing process to remove the first portion of the hard mask unit; and after the first removing process, performing a second removing process to remove the patterned polymeric mask.

In accordance with some embodiments of the present disclosure, for each of the first region and the second region, the inner layer fills spaces between the substrate and a bottommost one of the channel features, and between adjacent ones of channel features.

In accordance with some embodiments of the present disclosure, for each of the first region and the second region, the hard mask unit further includes interposing layers that are respectively disposed between the substrate and a bottommost one of the channel features, and between adjacent ones of channel features; and in removing the first portion of the hard mask unit, the outer layer, the inner layer and the interposing layers are sequentially removed using different etchants.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a base structure having a first region and a second region displaced from the first region;
forming a hard mask unit, the hard mask unit having a first portion and a second portion which are respectively formed on the first region and the second region, each of the first portion and the second portion of the hard mask unit including an inner layer and an outer layer that are sequentially formed on the base structure and that are made of different materials;
forming a patterned polymeric mask over the second portion of the hard mask unit, the first portion of the hard mask unit being exposed from the patterned polymeric mask;
after forming the patterned polymeric mask, performing a first removing process to remove the first portion of the hard mask unit; and
after the first removing process, performing a second removing process to remove the patterned polymeric mask.

2. The method of claim 1, wherein the first removing process includes:
applying a first etchant to remove the outer layer of the first portion of the hard mask unit; and
applying a second etchant that is different from the first etchant to remove the inner layer of the first portion of the hard mask unit.

3. The method of claim 2, wherein when the first etchant is applied, the outer layer exhibits an etching rate that is at least 80 times higher than an etching rate of the inner layer.

4. The method of claim 2, wherein when the second etchant is applied, the inner layer exhibits an etching rate that is at least 80 times higher than an etching rate of the outer layer.

5. The method of claim 1, wherein each of the inner layer and the outer layer independently includes silicon oxide, aluminum oxide, titanium nitride, titanium oxide, scandium oxide, yttrium oxide, lutetium oxide, lanthanum oxide, zinc oxide, strontium oxide, indium oxide, gallium oxide, erbium oxide, niobium oxide, silicon oxynitride, silicon nitride, polysilicon, amorphous silicon, a carbon-containing dielectric material, a nitride-containing dielectric material, a refractory metal, or combinations thereof.

6. The method of claim 1, wherein the protection mask unit has a thickness that ranges from 2 nm to 3 nm.

7. The method of claim 6, wherein each of the inner layer and the outer layer has a thickness that ranges from 0.5 nm to 1.5 nm.

8. A method for manufacturing a semiconductor structure, comprising:
forming a base structure having a first region and a second region displaced from the first region;
forming a hard mask unit, the hard mask unit having a first portion and a second portion which are respectively formed on the first region and the second region, each of the first portion and the second portion of the hard mask unit including an inner layer and an outer layer that are sequentially formed on the base structure;
forming a patterned polymeric mask over the second portion of the hard mask unit, the first portion of the hard mask unit being exposed from the patterned polymeric mask;
after forming the patterned polymeric mask, performing a first removing process to sequentially remove the outer layer and the inner layer of the first portion of the hard mask unit; and
after the first removing process, performing a second removing process to remove the patterned polymeric mask.

9. The method of claim 8, wherein, in the first removing process,
when a first etchant is applied to remove the outer layer of the first portion of the hard mask unit, the outer layer exhibits an etching rate that is at least 80 times higher than an etching rate of the inner layer, and
when a second etchant is applied to remove the inner layer of the first portion of the hard mask unit, the inner layer exhibits an etching rate that is at least 80 times higher than an etching rate of the outer layer.

10. The method of claim 8, wherein after the second removing process, the first region of the base structure and the second portion of the hard mask unit are exposed, and the method further comprises, after the second removing process,
forming an intermediate layer which has a first portion and a second portion, the first portion of the intermediate layer being formed over the first region of the base structure, and the second portion of the intermediate layer being formed over the second portion of the hard mask unit.

11. The method of claim 10, wherein:
each of the first region and the second region of the base structure includes channel features, and a gate dielectric layer having multiple portions that are respectively formed around the channel features; and
the intermediate layer is a dipole layer, the method further comprising:
performing a dipole drive-in process, dipole elements in the dipole layer diffusing into the gate dielectric layer at the first region, the second portion of the hard mask unit preventing diffusion of the dipole elements into the gate dielectric layer at the second region; and
removing the dipole layer after performing the dipole drive-in process.

12. The method of claim 11, further comprising, removing the second portion of the hard mask unit after removing the dipole layer.

13. The method of claim 8, before forming the hard mask unit, further comprising, forming an intermediate layer which has a first portion and a second portion that are respectively formed over the first region and the second region,
the hard mask unit being formed over the intermediate layer,
in the first removing process, a first portion of the intermediate layer exposed from the patterned polymeric mask being removed after removing the outer layer and the inner layer of the first portion of the hard mask unit, and
in the second removing process, after removing the patterned polymeric mask, the second portion of the hard mask unit being removed to leave the second portion of the intermediate layer as an intermediate element.

14. The method of claim 13, wherein:
each of the first region and the second region of the base structure includes channel features, and a gate dielectric layer having multiple portions that are respectively formed around the channel features; and
the intermediate element is formed to cover the gate dielectric layer at the second region.

15. The method of claim 14, wherein the intermediate element is a first work function metal feature, and the method further comprises, after removing the patterned polymeric mask and the second portion of the hard mask unit, forming a second work function metal feature over the first region and the second region, a material of the first work function metal feature being different from a material of the second work function metal feature.

16. The method of claim 14, wherein the intermediate feature is a dipole feature, and the method further comprises, after removing the patterned polymeric mask and the second portion of the hard mask unit:
performing a dipole drive-in process such that dipole elements in the dipole feature diffuse into the gate dielectric layer at the second region; and
after the dipole drive-in process, removing the dipole feature.

17. The method of claim 14, wherein the intermediate layer is a diffusion barrier feature, and the method further comprises, after removing the patterned polymeric mask and the second portion of the hard mask unit:
forming a dipole layer over the first region and the second region;
performing a dipole drive-in process such that dipole elements in the dipole layer diffuse into the gate dielectric layer at the first region, penetration of the dipole elements in the dipole layer into the gate dielectric layer at the second region being blocked by the diffusion barrier feature; and
after the dipole drive-in process, removing the dipole layer and the diffusion barrier feature.

18. A method for manufacturing a semiconductor structure, comprising:
forming a base structure on a substrate, the base structure having a first region and a second region displaced from the first region, each of the first region and the second region including:
two source/drain features formed on the substrate; and
channel features that are spaced apart from each other in a vertical direction and that interconnect the two source/drain features;
forming a hard mask unit, the hard mask unit having a first portion and a second portion which are respectively formed on the first region and the second region, each of the first portion and the second portion of the hard mask unit including an inner layer and an outer layer that are sequentially formed on the channel features and that are made of different materials;
forming a patterned polymeric mask over the second portion of the hard mask unit, the first portion of the hard mask unit being exposed from the patterned polymeric mask;
after forming the patterned polymeric mask, performing a first removing process to remove the first portion of the hard mask unit; and
after the first removing process, performing a second removing process to remove the patterned polymeric mask.

19. The method of claim 18, wherein for each of the first region and the second region, the inner layer fills spaces between the substrate and a bottommost one of the channel features, and between adjacent ones of channel features.

20. The method of claim 18, wherein
for each of the first region and the second region, the hard mask unit further includes interposing layers that are respectively disposed between the substrate and a bottommost one of the channel features, and between adjacent ones of channel features; and
in removing the first portion of the hard mask unit, the outer layer, the inner layer and the interposing layers are sequentially removed using different etchants.
